(19) United States
(12) Patent Application Publication
(10) Pub. No.: US 2026/0107448 A1
(43) Pub. Date: Apr. 16, 2026

(54) SEMICONDUCTOR DEVICE WITH PROTRUDING CONTACT AND METHOD OF FABRICATING THE SAME

(71) Applicant: NANYA TECHNOLOGY CORPORATION, NEW TAIPEI CITY (TW)

(72) Inventor: PING HSU, NEW TAIPEI CITY (TW)

(21) Appl. No.: 18/916,364

(22) Filed: Oct. 15, 2024

(51) Int. Cl. H10B 12/00

(52) U.S. Cl. CPC H10B 12/485; H10B 12/0335; H10B 12/315

(57) ABSTRACT

The present application discloses a semiconductor device with a protruding contact and a method of fabricating the semiconductor device. The semiconductor device includes a substrate, a bit line structure on the substrate, a capacitor contact structure next to the bit line structure, and a landing pad layer covering a portion of a top surface of the capacitor contact structure and an upper portion of a sidewall of the capacitor contact structure.

### TECHNICAL FIELD

The present disclosure relates to a semiconductor device and a method of fabricating the semiconductor device, and more particularly, to a semiconductor device with a protruding contact and a method of fabricating the semiconductor device with the protruding contact.

### DISCUSSION OF THE BACKGROUND

Semiconductor devices are used in various electronic applications, including personal computers, cellular telephones, digital cameras, and other electronic equipment. Sizes of semiconductor devices are continuously decreasing to meet growing demands for computing power. However, such scaling down presents challenges that are becoming more frequent and impactful. Therefore, there are still challenges to improving quality, yield, performance and reliability while reducing complexity.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device comprising a substrate, a shallow trench isolation (STI) structure disposed in the substrate, a capacitor contact structure protruding from the substrate, and a landing pad covering a portion of a top surface of the capacitor contact structure and an upper portion of a sidewall of the capacitor contact structure. The substrate comprises a bottom semiconductor layer, a top semiconductor layer disposed over the bottom semiconductor layer, and a buried insulating layer disposed between the top semiconductor layer and the bottom semiconductor layer.

In some embodiments, the shallow trench isolation (STI) structure penetrates through the top semiconductor layer and the buried insulating layer and extends into the bottom semiconductor layer.

In some embodiments, the shallow trench isolation (STI) structure comprises a first liner disposed in the substrate, a second liner disposed over the first liner, a third liner disposed over the second liner, and a trench-filling layer disposed over the third liner and separated from the second liner by the third liner.

In some embodiments, the first liner comprises a first portion and a second portion covering opposite sidewalls of the buried insulating layer, and a third portion separating the second liner from the bottom semiconductor layer.

In some embodiments, the first portion, the second portion and the third portion are separated from each other.

In some embodiments, the first liner, the second liner and the third liner are made of different materials.

In some embodiments, the bottom semiconductor layer and the top semiconductor layer are formed of silicon, and the buried insulating layer is formed of a nitride.

In some embodiments, the capacitor contact structure comprises a liner layer disposed on the substrate and extending into the substrate, a capacitor conductive structure disposed over and surrounded by the liner layer, and a spacer structure surrounding the capacitor conductive structure and separated from the capacitor conductive structure by the liner layer.

In some embodiments, a bottom surface of the liner layer is lower than a top surface of the substrate, and the bottom surface of the liner layer is higher than a bottom surface of the buried insulating layer.

In some embodiments, an angle between a sidewall of the liner layer and the bottom surface of the liner layer is greater than 90 degrees.

In some embodiments, the capacitor conductive structure extends into the substrate and has a tapered profile.

In some embodiments, the capacitor conductive structure comprises a barrier layer conformally disposed over and surrounded by the liner layer, a metal layer disposed over and surrounded by the barrier layer, and a metal filling portion disposed over and surrounded by the metal layer.

In some embodiments, the metal filling portion has a top width and a bottom width, wherein the top width is greater than the bottom width.

In some embodiments, the spacer structure comprises an L-shaped liner and a porous low-k dielectric layer disposed over the L-shaped liner.

In some embodiments, the porous low-k dielectric layer is enclosed by the liner layer and the L-shaped liner.

Another aspect of the present disclosure provides a semiconductor device comprising a substrate with a plurality of shallow trench isolation (STI) structures disposed therein, a capacitor contact structure disposed in the substrate and protruding from the substrate, a bit line structure disposed on the substrate and disposed next to the capacitor contact structure, a bit line contact disposed under the bit line structure, and a landing pad covering a portion of a top surface of the capacitor contact structure and an upper portion of a sidewall of the capacitor contact structure.

In some embodiments, the substrate comprises a bottom semiconductor layer, a top semiconductor layer disposed over the bottom semiconductor layer and a buried insulating layer disposed between the top semiconductor layer and the bottom semiconductor layer.

In some embodiments, the shallow trench isolation (STI) structures define an active area, wherein a plurality of source/drain regions are disposed in the active area.

In some embodiments, the shallow trench isolation (STI) structures penetrate through the top semiconductor layer and the buried insulating layer and extend into the bottom semiconductor layer.

In some embodiments, the shallow trench isolation (STI) structure comprises a first liner disposed in the substrate, a second liner disposed over the first liner, a third liner disposed over the second liner, and a trench-filling layer disposed over the third liner and separated from the second liner by the third liner.

In some embodiments, the first liner comprises a first portion and a second portion covering opposite sidewalls of the buried insulating layer, and a third portion separating the second liner from the bottom semiconductor layer.

In some embodiments, the first portion, the second portion and the third portion are separated from each other.

In some embodiments, the first liner, the second liner and the third liner are made of different materials.

In some embodiments, the capacitor contact structure comprises a liner layer disposed on the substrate and extending into the substrate, a capacitor conductive structure disposed over and surrounded by the liner layer, and a spacer structure surrounding the capacitor conductive structure and separated from the capacitor conductive structure by the liner layer.

In some embodiments, a bottom surface of the liner layer is lower than a top surface of the substrate, wherein the bottom surface of the liner layer is higher than a bottom surface of the buried insulating layer.

In some embodiments, the capacitor conductive structure extends into the substrate and has a tapered profile.

In some embodiments, the capacitor conductive structure comprises a barrier layer conformally disposed over and surrounded by the liner layer, a metal layer disposed over and surrounded by the barrier layer, and a metal filling portion disposed over and surrounded by the metal layer.

In some embodiments, the metal filling portion has a top width and a bottom width, wherein the top width is greater than the bottom width.

In some embodiments, the spacer structure comprises an L-shaped liner and a porous low-k dielectric layer disposed over the L-shaped liner.

In some embodiments, the porous low-k dielectric layer is enclosed by the liner layer and the L-shaped liner.

In some embodiments, a top surface of the bit line structure is at a vertical level lower than a vertical level of a top surface of the capacitor contact structure.

In some embodiments, the semiconductor device further comprises a bit line spacer disposed between the capacitor contact structure and the bit line structure.

In some embodiments, a top surface of the bit line spacer is substantially coplanar with the top surface of the bit line structure.

In some embodiments, the bit line structure comprises a bit line bottom conductive layer disposed on the substrate, a bit line middle conductive layer disposed on the bit line bottom conductive layer, a bit line top conductive layer disposed on the bit line middle conductive layer, and a bit line capping layer disposed on the bit line top conductive layer.

In some embodiments, a top surface of the bit line contact is substantially coplanar with a top surface of the substrate.

Another aspect of the present disclosure provides a method for fabricating a semiconductor device comprising providing a substrate, forming a bit line structure on the substrate, forming a capacitor contact structure next to the bit line structure, recessing a top surface of the bit line structure, and forming a landing pad layer covering a portion of a top surface of the capacitor contact structure and an upper portion of a sidewall of the capacitor contact structure.

In some embodiments, the formation of the bit line structure comprises forming a bit line bottom conductive layer on the substrate, forming a bit line middle conductive layer on the bit line bottom conductive layer, forming a bit line top conductive layer on the bit line middle conductive layer, and forming a bit line capping layer on the bit line top conductive layer.

In some embodiments, the formation of the capacitor contact structure comprises forming a spacer structure on the substrate, forming a liner layer on the substrate and extending into the substrate, wherein the liner layer is surrounded by the spacer structure, and forming a capacitor conductive structure over and surrounded by the liner layer, wherein the capacitor conductive structure comprises a barrier layer conformally disposed over and surrounded by the liner layer, a metal layer disposed over and surrounded by the barrier layer, and a metal filling portion disposed over and surrounded by the metal layer.

In some embodiments, the method further comprises forming a bit line spacer between the capacitor contact structure and the bit line structure, wherein a top surface of the bit line spacer is substantially coplanar with the top surface of the bit line structure.

In some embodiments, the method further comprises forming a bit line contact under the bit line structure.

In some embodiments, the method further comprises forming source/drain regions under the bit line contact and the capacitor contact structure.

In some embodiments, the method further comprises forming a shallow trench isolation (STI) structure in the substrate.

In some embodiments, the formation of the shallow trench isolation (STI) structure comprises forming a first liner in the substrate, forming a second liner disposed over the first liner, forming a third liner disposed over the second liner, and forming a trench-filling layer disposed over the third liner, wherein the trench-filling layer is separated from the second liner by the third liner.

Due to the design of the semiconductor device of the present disclosure, a contact surface between a landing pad layer and a capacitor contact structure may be increased. Accordingly, a resistance between the landing pad layer and the capacitor contact structure may be reduced. As a result, power consumption of the semiconductor device may be reduced. In addition, a protruding capacitor contact structure may provide sufficient support for the landing pad layer.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in flowchart diagram form, a method of fabricating a semiconductor device in accordance with one embodiment of the present disclosure.

FIG. 2 illustrates, in a schematic top-view diagram, an intermediate semiconductor device in accordance with one embodiment of the present disclosure.

FIG. 3 is a schematic cross-sectional view diagram along line A-A′ in FIG. 2.

FIG. 4 is a schematic cross-sectional view diagram along line B-B′ in FIG. 2.

FIG. 5 illustrates, in a schematic top-view diagram, an intermediate semiconductor device in accordance with one embodiment of the present disclosure.

FIG. 6 is a schematic cross-sectional view diagram along line B-B′ in FIG. 5.

FIG. 7 illustrates, in a schematic top-view diagram, an intermediate semiconductor device in accordance with one embodiment of the present disclosure.

FIG. 8 is a schematic cross-sectional view diagram along line B-B′ in FIG. 7.

FIG. 9 illustrates, in a schematic top-view diagram, an intermediate semiconductor device in accordance with one embodiment of the present disclosure.

FIG. 10 is a schematic cross-sectional view diagram along line A-A′ in FIG. 9.

FIG. 11 is a schematic cross-sectional view diagram along line B-B′ in FIG. 9.

FIG. 12 illustrates, in a schematic top-view diagram, an intermediate semiconductor device in accordance with one embodiment of the present disclosure.

FIG. 13 is a schematic cross-sectional view diagram along line A-A′ in FIG. 12.

FIG. 14 is a schematic cross-sectional view diagram along line B-B′ in FIG. 12.

FIG. 15 is a schematic cross-sectional view diagram along line A-A′ in FIG. 12.

FIG. 16 is a schematic cross-sectional view diagram along line B-B′ in FIG. 12.

FIG. 17 illustrates, in a schematic top-view diagram, an intermediate semiconductor device in accordance with one embodiment of the present disclosure.

FIG. 18 is a schematic cross-sectional view diagram along line A-A′ in FIG. 17.

FIG. 19 is a schematic cross-sectional view diagram along line B-B′ in FIG. 17.

FIG. 20 is a schematic cross-sectional view diagram along line A-A′ in FIG. 17.

FIG. 21 is a schematic cross-sectional view diagram along line B-B′ in FIG. 17.

FIG. 22 illustrates, in a schematic top-view diagram, an intermediate semiconductor device in accordance with one embodiment of the present disclosure.

FIG. 23 is a schematic cross-sectional view diagram along line A-A′ in FIG. 22.

FIG. 24 is a schematic cross-sectional view diagram along line B-B′ in FIG. 22.

FIG. 25 is a schematic cross-sectional view diagram along line A-A′ in FIG. 22.

FIG. 26 is a schematic cross-sectional view diagram along line B-B′ in FIG. 22.

FIG. 27 is a schematic cross-sectional view diagram along line A-A′ in FIG. 22.

FIG. 28 illustrates, in a schematic top-view diagram, an intermediate semiconductor device in accordance with one embodiment of the present disclosure.

FIG. 29 is a schematic cross-sectional view diagram along a A-A′ in FIG. 28.

FIGS. 30 to 36 are schematic cross-sectional view diagrams along line A-A′ in FIG. 12 illustrating flows of fabricating semiconductor devices in accordance with some embodiments of the present disclosure.

FIGS. 37 to 44 are schematic cross-sectional view diagrams along line A-A′ in FIG. 17 illustrating flows of fabricating semiconductor devices in accordance with some embodiments of the present disclosure.

FIGS. 45 to 48 are schematic cross-sectional view diagrams along line A-A′ in FIG. 17 illustrating flows of fabricating semiconductor devices in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect such meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the axis Z, and below (or down) corresponds to the opposite direction of the arrow of the axis Z.

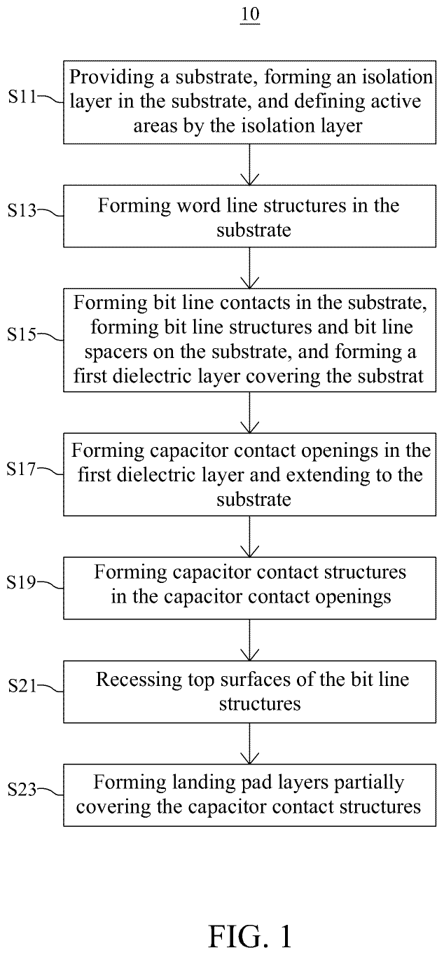

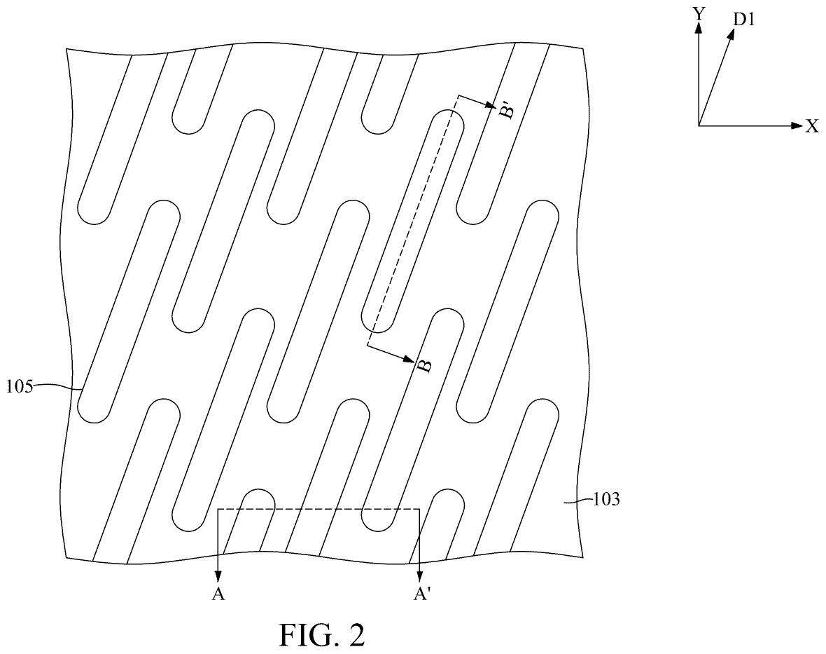

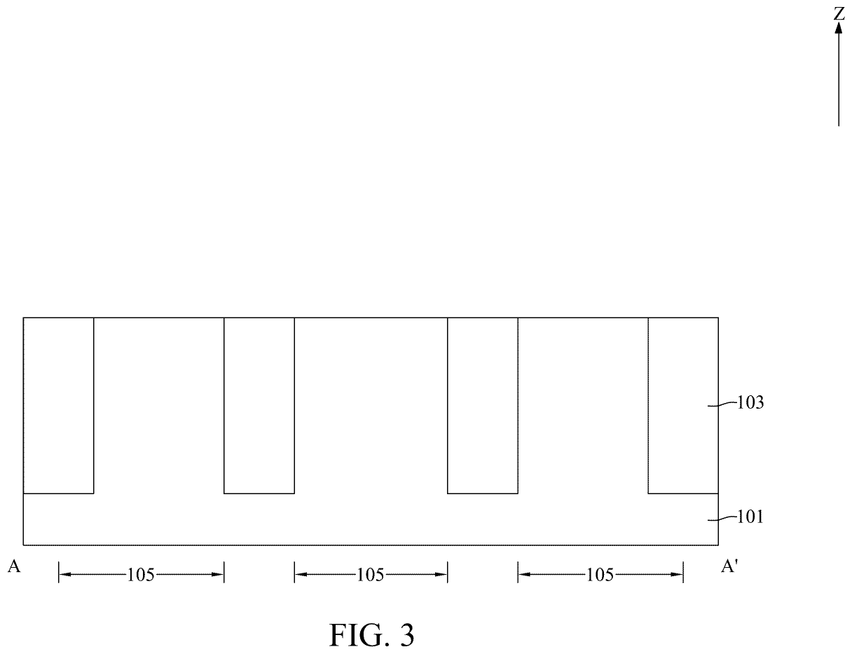

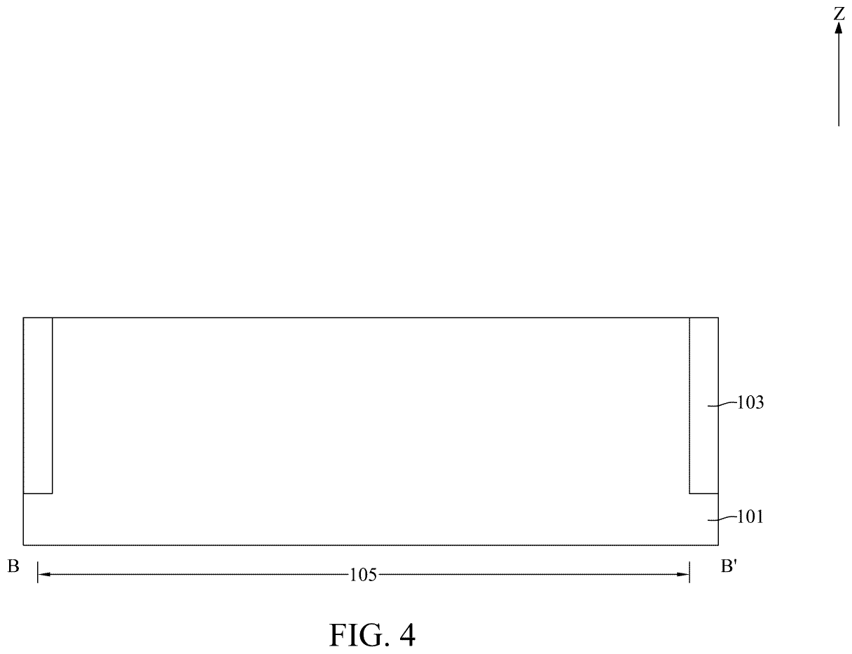

FIG. 1 illustrates, in flowchart diagram form, a method 10 of fabricating a semiconductor device 1A in accordance with one embodiment of the present disclosure. FIG. 2 illustrates, in a schematic top-view diagram, an intermediate semiconductor device in accordance with one embodiment of the present disclosure. FIGS. 3 and 4 are schematic cross-sectional view diagrams along lines A-A′ and B-B′ in FIG. 2, respectively, illustrating part of a process of fabricating the semiconductor device 1A in accordance with one embodiment of the present disclosure.

With reference to FIGS. 1 to 4, in step S11, a substrate 101 may be provided, an isolation layer 103 may be formed in the substrate 101, and a plurality of active areas 105 may be defined by the isolation layer 103.

With reference to FIGS. 2 to 4, the substrate 101 may include an organic semiconductor or a layered semiconductor such as silicon/silicon germanium, silicon-on-insulator or silicon germanium-on-insulator. When the substrate 101 is formed of silicon-on-insulator, the substrate 101 may include a top semiconductor layer and a bottom semiconductor layer formed of silicon, and a buried insulating layer which may separate the top semiconductor layer from the bottom semiconductor layer. The buried insulating layer may include, for example, a crystalline oxide, a non-crystalline oxide, a nitride, or a combination thereof.

With reference to FIGS. 2 to 4, the isolation layer 103 may be formed in the substrate 101. In some embodiments, a top surface of the isolation layer 103 may be substantially coplanar with a top surface of the substrate 101. The isolation layer 103 may be formed of, for example, an insulating material such as silicon oxide, silicon nitride, silicon oxynitride, silicon nitride oxide, or fluoride-doped silicate. It should be noted that, in the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

With reference to FIGS. 2 to 4, the isolation layer 103 may surround portions of the substrate 101. The surrounded portions of the substrate 101 may be referred to as the active areas 105. From a top-view perspective, the active areas 105 may be bar shapes. Each of the active areas 105 may extend in a first direction D1. The active areas 105 may be arranged along a first axis X and a second axis Y. The active areas 105 may be spaced apart from each other in the first direction D1. The first axis X and the second axis are perpendicular to each other. The first direction D1 may be slanted with respect to the first axis X and the second axis Y.

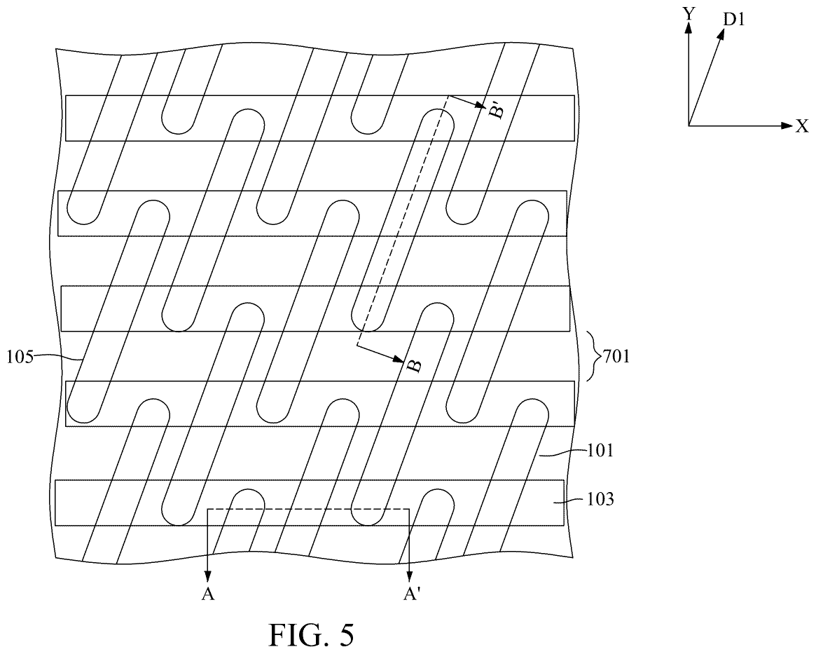

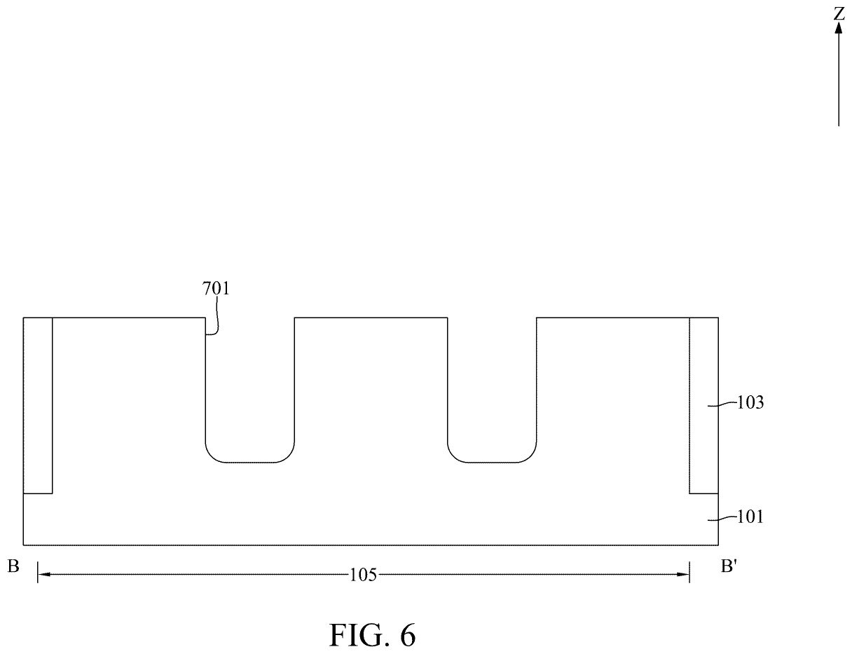

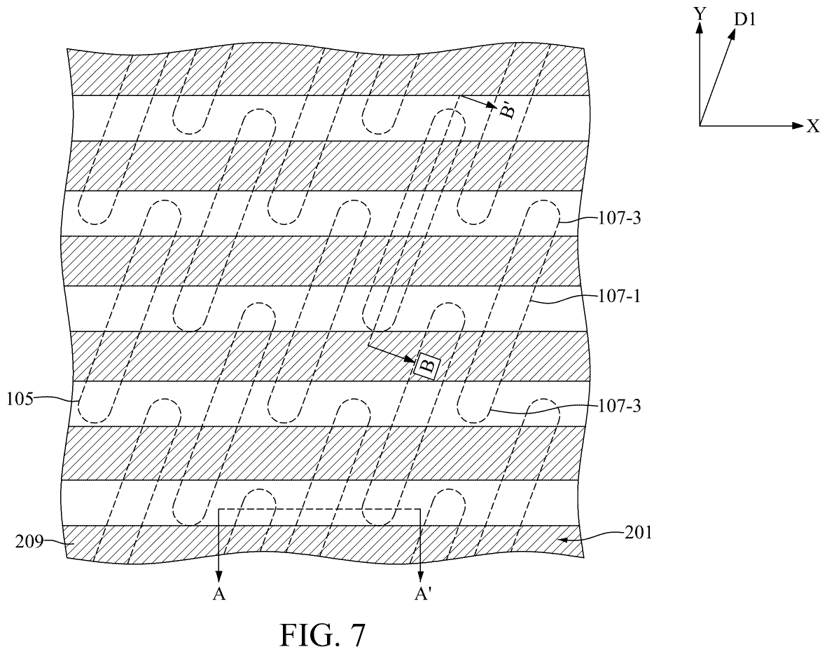

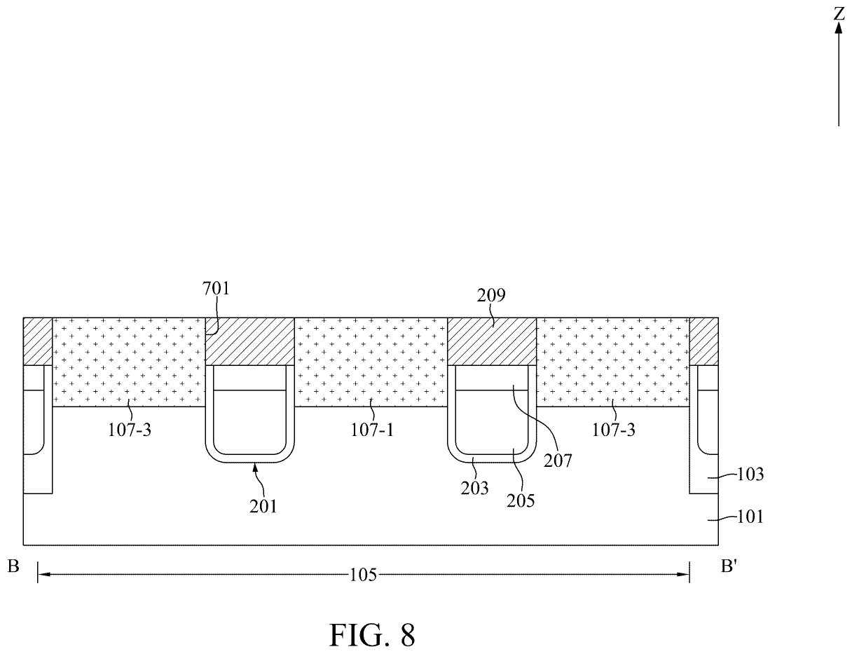

FIG. 5 illustrates, in a schematic top-view diagram, an intermediate semiconductor device in accordance with one embodiment of the present disclosure. FIG. 6 is a schematic cross-sectional view diagram along line B-B′ in FIG. 5 illustrating part of a process of fabricating the semiconductor device 1A in accordance with one embodiment of the present disclosure. FIG. 7 illustrates, in a schematic top-view diagram, an intermediate semiconductor device in accordance with one embodiment of the present disclosure. FIG. 8 is a schematic cross-sectional view diagram along line B-B′ in FIG. 7 illustrating part of a process of fabricating the semiconductor device 1A in accordance with one embodiment of the present disclosure.

With reference to FIG. 1 and FIGS. 5 to 8, in step S13, a plurality of word line structures 201 may be formed in the substrate 101.

With reference to FIGS. 5 and 6, a plurality of word line structure trenches 701 may be formed in the substrate 101. From a top-view perspective, the word line structure trenches 701 may extend along the first axis X and are parallel to each other. The word line structure trenches 701 may be arranged along the second axis Y. Each of the active areas 105 may intersect two of the word line structure trenches 701. In some embodiments, two of the word line structure trenches 701 may divide the corresponding active area 105 into three segments. In some embodiments, from a cross-sectional perspective, bottom surfaces of the word line structure trenches 701 may be flat. In some embodiments, during a fabrication of the semiconductor device 1A, the bottom surfaces of the word line structure trenches 701 may be rounded to reduce defect density and reduce electric field concentration. The rounded bottom surfaces may reduce corner effects of the word line structure trenches 701.

It should be noted that, in the present disclosure, the term “segment” may be interchangeably used with the term “portion.”

With reference to FIGS. 7 and 8, a plurality of word line dielectric layers 203 may be conformally formed in the word line structure trenches 701, respectively. The word line dielectric layers 203 may have U-shaped cross-sectional profiles. In some embodiments, the word line dielectric layers 203 may be formed by a thermal oxidation process. For example, the word line dielectric layers 203 may be formed by oxidizing the bottom surfaces and sidewalls of the word line structure trenches 701.

In some embodiments, the word line dielectric layers 203 may be formed by a deposition process such as chemical vapor deposition or atomic layer deposition. The word line dielectric layers 203 may include a high-k material, an oxide such as silicon oxide, a nitride such as silicon nitride, an oxynitride such as silicon oxynitride, or a combination thereof. The high-k material may include a hafnium-containing material. The hafnium-containing material may be, for example, a hafnium oxide, a hafnium silicon oxide, a hafnium silicon oxynitride, or a combination thereof. In some embodiments, the high-k material may be, for example, a lanthanum oxide, a lanthanum aluminum oxide, a zirconium oxide, a zirconium silicon oxide, a zirconium silicon oxynitride, an aluminum oxide, or a combination thereof.

With reference to FIGS. 7 and 8, a plurality of word line bottom conductive layers 205 may be respectively formed on the word line dielectric layers 203 and in the word line structure trenches 701. In some embodiments, a plurality of word line top conductive layers 207 may be respectively formed on the word line bottom conductive layers 205 and in the word line structure trenches 701. As shown in FIG. 8, top surfaces of the word line top conductive layers 207 may be at a vertical level lower than the top surface of the substrate 101.

The word line bottom conductive layers 205 may be formed of, for example, polycrystalline silicon, polycrystalline germanium, polycrystalline silicon germanium, the like, or a combination thereof. In some embodiments, the word line bottom conductive layers 205 may be doped with a dopant such as phosphorus, arsenic, antimony, or boron. The word line top conductive layers 207 may be formed of, for example, tungsten, aluminum, titanium, copper, titanium nitride, the like, or a combination thereof.

With reference to FIGS. 7 and 8, a plurality of word line capping layers 209 may be respectively formed on the word line top conductive layers 207. In some embodiments, top surfaces of the word line capping layers 209 may be substantially coplanar with the top surface of the substrate 101. The word line capping layers 209 may be formed of, for example, silicon oxide, silicon nitride, silicon oxynitride, other semiconductor oxides, other semiconductor nitrides, or a combination thereof.

With reference to FIGS. 7 and 8, the word line dielectric layers 203, the word line bottom conductive layers 205, the word line top conductive layers 207, and the word line capping layers 209 together form the word line structures 201. From a top-view perspective, the word line structures 201 may extend along the first axis X and are parallel to each other. The word line structures 201 may be arranged along the second axis Y. Each of the active areas 105 may intersect two of the word line structures 201.

With reference to FIGS. 7 and 8, an implantation process may be performed over the substrate 101. From a cross-sectional perspective, after the implantation process is performed, source/drain regions 107-1 and 107-3 may be formed in upper portions of the active areas 105. From a top-view perspective, for each of the active areas 105, the source region 107-1 may be formed between the two of the word line structures 201 intersecting the active area 105. The drain regions 107-3 may be formed at two ends of the active area 105. The source/drain regions 107-1 and 107-3 may be doped with a dopant such as phosphorus, arsenic, antimony, or boron.

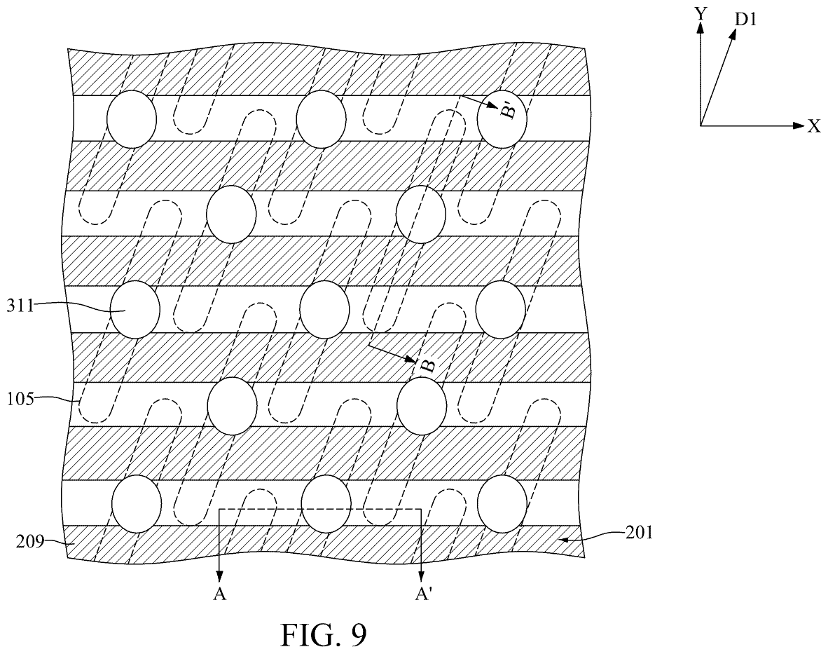

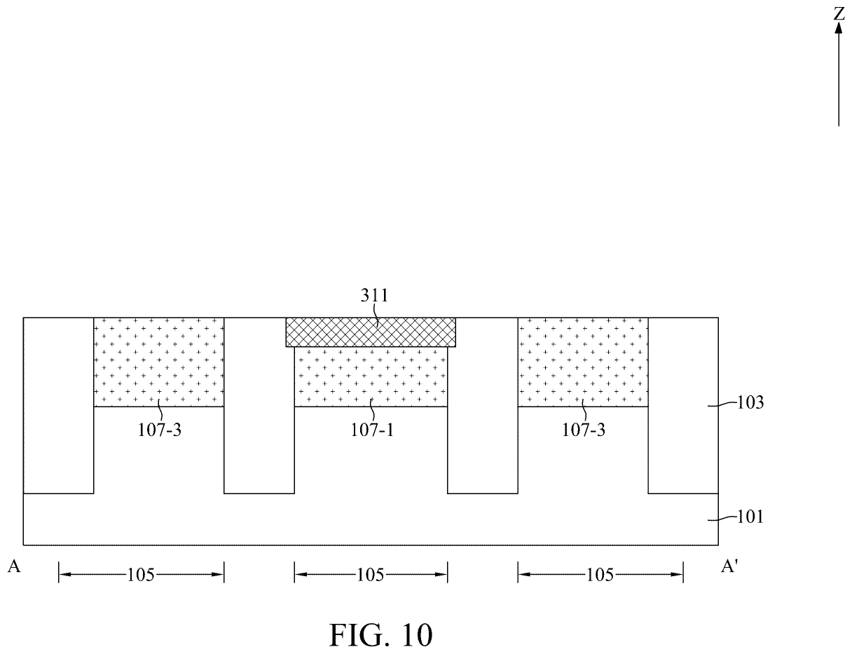

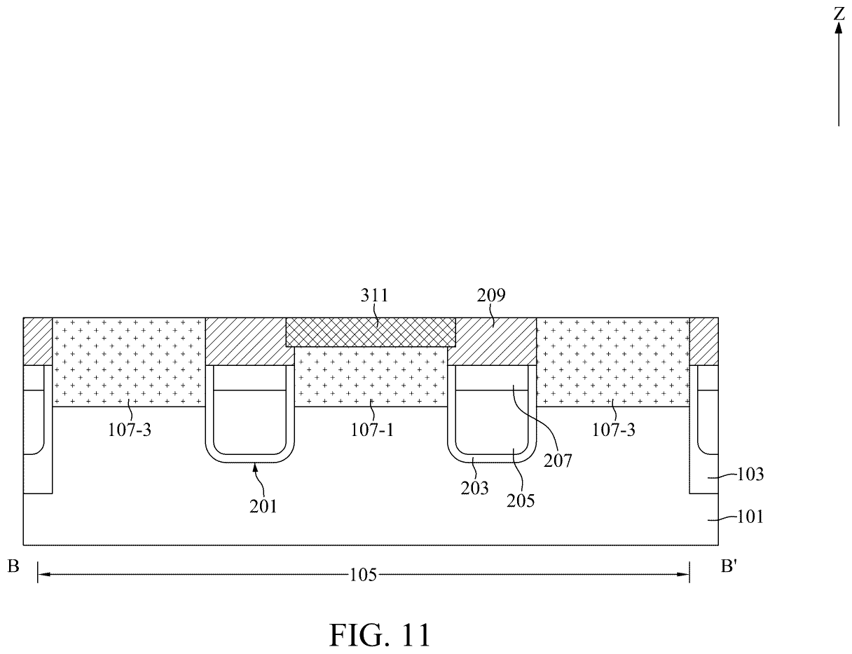

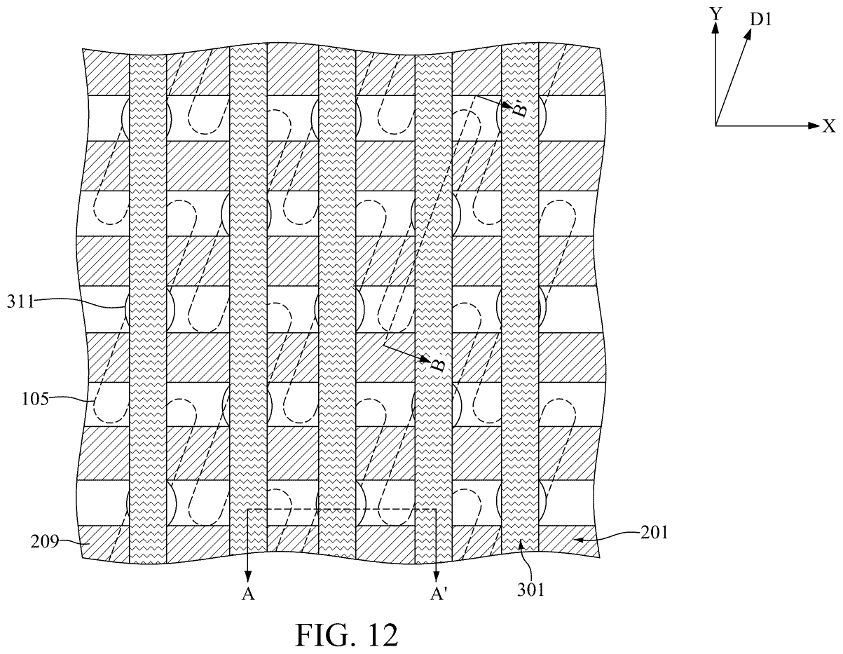

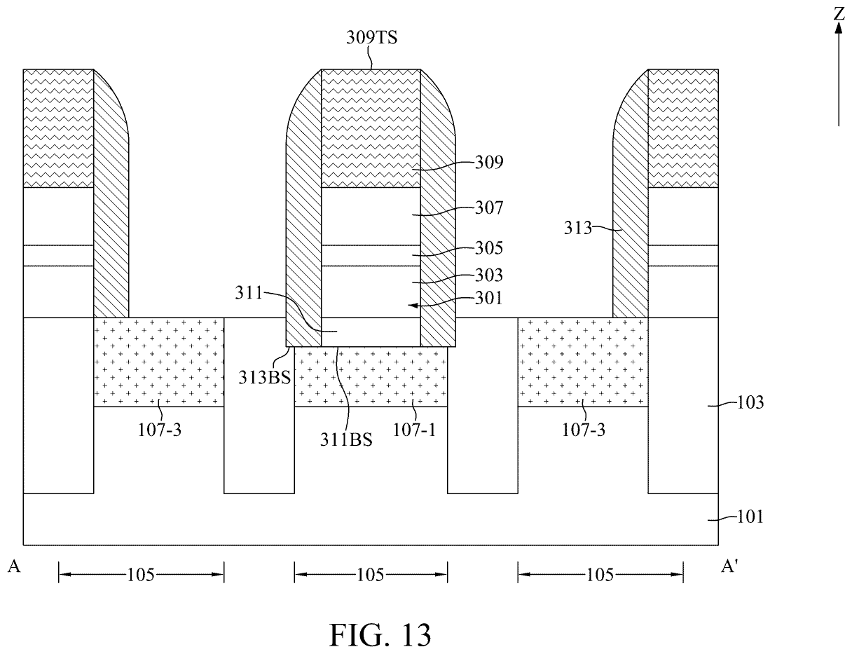

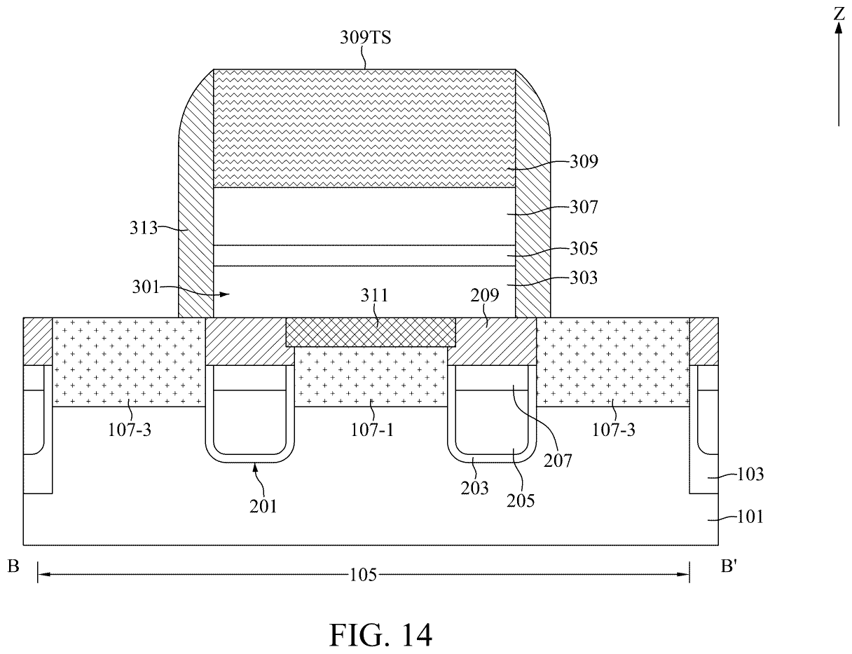

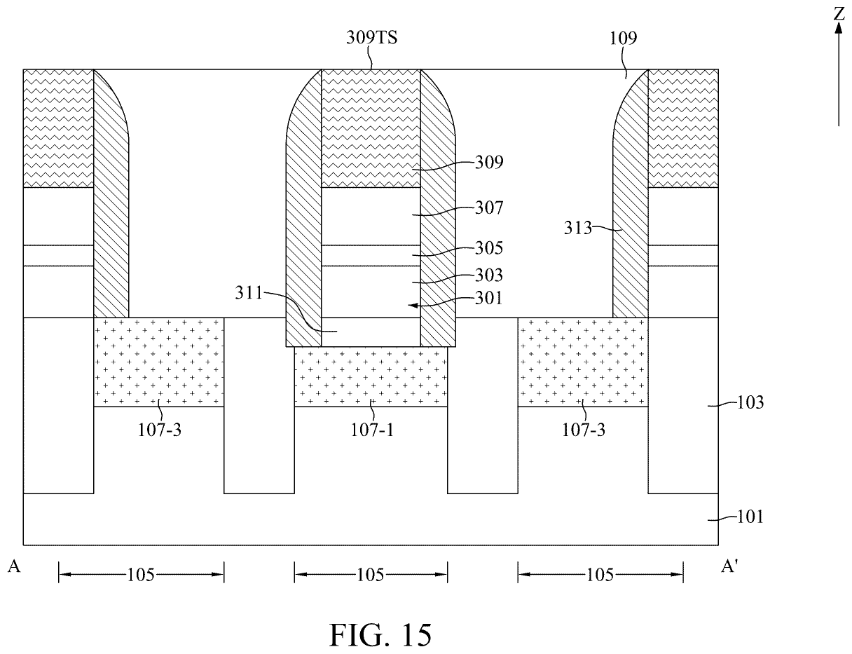

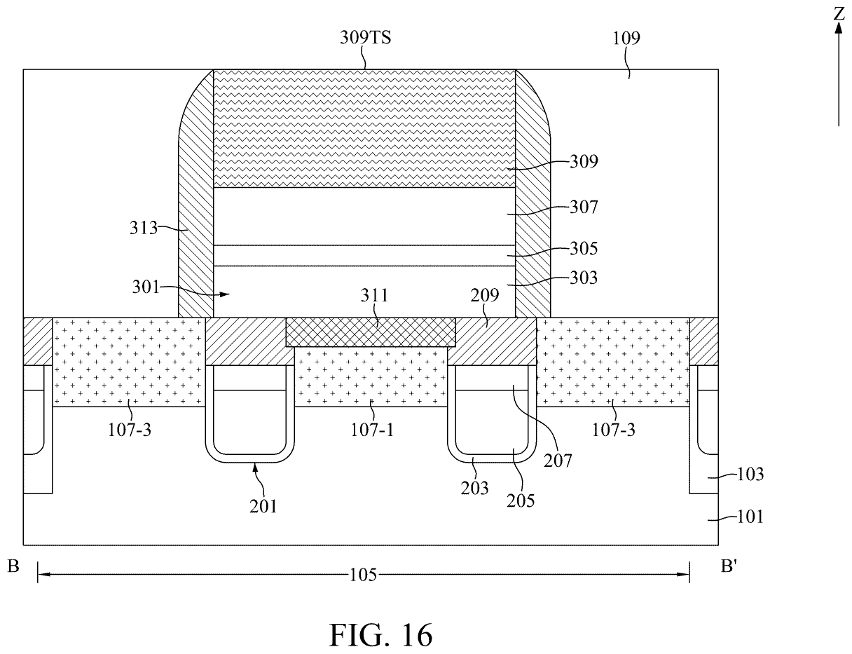

FIG. 9 illustrates, in a schematic top-view diagram, an intermediate semiconductor device in accordance with one embodiment of the present disclosure. FIGS. 10 and 11 are schematic cross-sectional view diagrams along lines A-A′ and B-B′ in FIG. 9, respectively, illustrating part of a process of fabricating the semiconductor device 1A in accordance with one embodiment of the present disclosure. FIG. 12 illustrates, in a schematic top-view diagram, an intermediate semiconductor device in accordance with one embodiment of the present disclosure. FIGS. 13 and 14 are schematic cross-sectional view diagrams along lines A-A′ and B-B′ in FIG. 12, respectively, illustrating part of a process of fabricating the semiconductor device 1A in accordance with one embodiment of the present disclosure. FIGS. 15 and 16 are schematic cross-sectional view diagrams along lines A-A′ and B-B′ in FIG. 12, respectively, illustrating part of a process of fabricating the semiconductor device 1A in accordance with one embodiment of the present disclosure.

With reference to FIG. 1 and FIGS. 9 to 16, in step S15, a plurality of bit line contacts 311 may be formed in the substrate 101, and a plurality of bit line structures 301 and a plurality of bit line spacers 313 may be formed on the substrate 101.

With reference to FIGS. 9 to 11, the bit line contacts 311 may be respectively formed in the source regions 107-1. In some embodiments, a top surface of the bit line contact 311 may be substantially coplanar with the top surface of the substrate 101. The bit line contact 311 may be formed of, for example, tungsten, cobalt, zirconium, tantalum, titanium, aluminum, ruthenium, copper, metal carbides (e.g., tantalum carbide, titanium carbide, tantalum magnesium carbide), metal nitrides (e.g., titanium nitride), transition metal aluminides, or a combination thereof. The bit line contact 311 may be electrically coupled to the source region 107-1.

With reference to FIGS. 12 to 14, a series of deposition processes may be sequentially performed to deposit a bit line bottom conductive layer 303, a bit line middle conductive layer 305, a bit line top conductive layer 307, and a bit line capping layer 309 over the substrate 101. Subsequently, a photolithography process and an etch process may be applied to pattern the aforementioned layers. The patterned layers may together form the bit line structure 301.

From a cross-sectional perspective, the bit line structure 301 may be formed on the bit line contact 311. In some embodiments, a top surface 309TS of the bit line capping layer 309 may be referred to as a top surface of the bit line structure 301. In some embodiments, during the etch process, a portion of the bit line contact 311 may be removed as shown in FIG. 13. From a top-view perspective, the bit line structures 301 may extend along the second axis Y and may be parallel to each other. The bit line structures 301 may be arranged along the first axis X. In some embodiments, the bit line structures 301 may intersect the word line structures 201. The bit line structure 301 may be electrically coupled to the source region 107-1 through the bit line contact 311.

The bit line bottom conductive layer 303 may be formed of, for example, polycrystalline silicon, polycrystalline germanium, polycrystalline silicon germanium, titanium, tantalum, tungsten, copper, aluminum, tungsten silicide, cobalt silicide, or titanium silicide. The bit line middle conductive layer 305 may be formed of, for example, titanium nitride or tantalum nitride. The bit line top conductive layer 307 may be formed of, for example, tungsten, tantalum, titanium, copper, or aluminum. The bit line middle conductive layer 305 may reduce or possibly prevent conductive material in the bit line top conductive layer 307 from diffusing toward the bit line bottom conductive layer 303. The bit line capping layer 309 may be formed of, for example, silicon nitride, silicon nitride oxide, silicon oxynitride, boron nitride, silicon boron nitride, phosphorus boron nitride, or boron carbon silicon nitride.

With reference to FIGS. 12 to 14, a layer of spacer material may be formed to cover the bit line structure 301 and the substrate 101. The spacer material may be, for example, silicon oxide, silicon nitride, silicon carbon nitride, silicon nitride oxide, or silicon oxynitride. An etch process, such as an anisotropic dry etch process, may be performed to remove portions of the layer of spacer material and concurrently form the bit line spacers 313 on sidewalls of the bit line structure 301. In some embodiments, portions of bottom surfaces 313BS of the bit line spacers 313 may be substantially coplanar with a bottom surface 311BS of the bit line contact 311 as shown in FIG. 13.

In some embodiments, after the formation of the bit line contact 311, an interlayer may be formed on the substrate 101. The bit line structure 301 may be formed on the interlayer. The interlayer may be formed of, for example, carbon-doped oxide, carbon-incorporated silicon oxide, or nitrogen-doped silicon carbide.

With reference to FIGS. 15 and 16, a first dielectric layer 109 may be formed to cover the substrate 101 and the bit line structure 301. A planarization process, such as chemical mechanical polishing, may be performed until the top surface 309TS of the bit line capping layer 309 is exposed to remove excess material and provide a substantially flat surface for subsequent processing steps. The first dielectric layer 109 may be formed of, for example, silicon oxide, undoped silicate glass, fluorosilicate glass, borophosphosilicate glass, a low-k dielectric material, or a combination thereof. The low-k dielectric material may have a dielectric constant less than 3.0 or even less than 2.5. In some embodiments, the low-k dielectric material may have a dielectric constant less than 2.0.

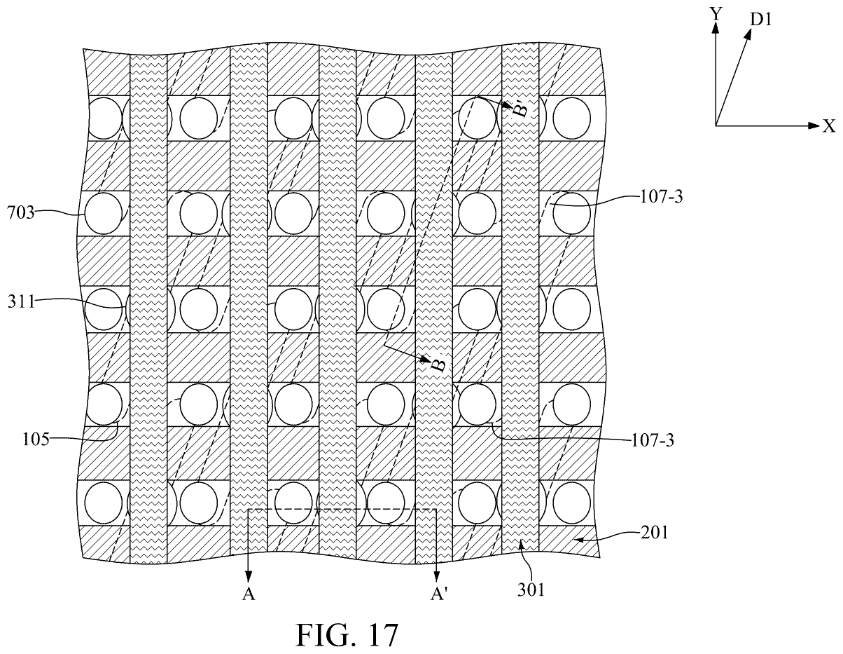

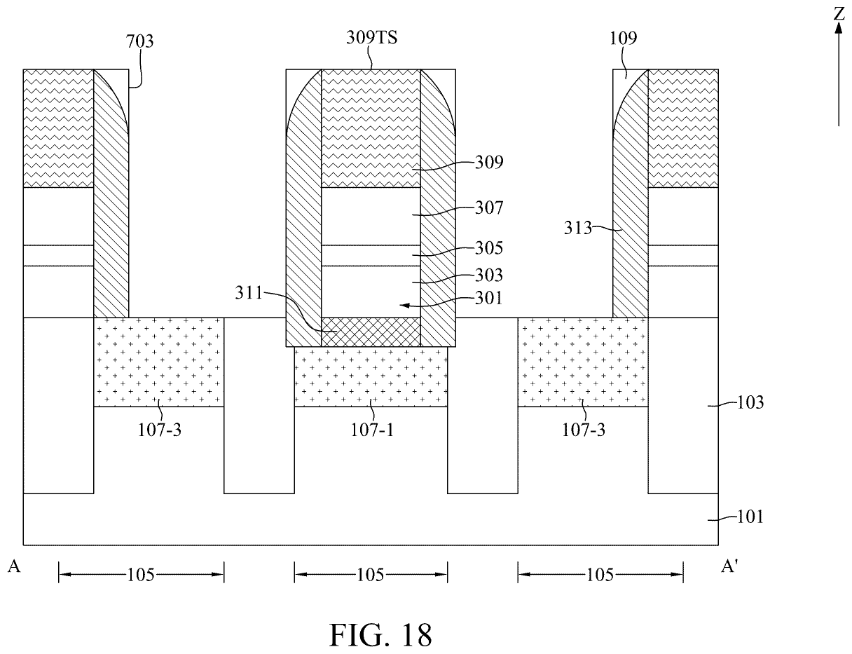

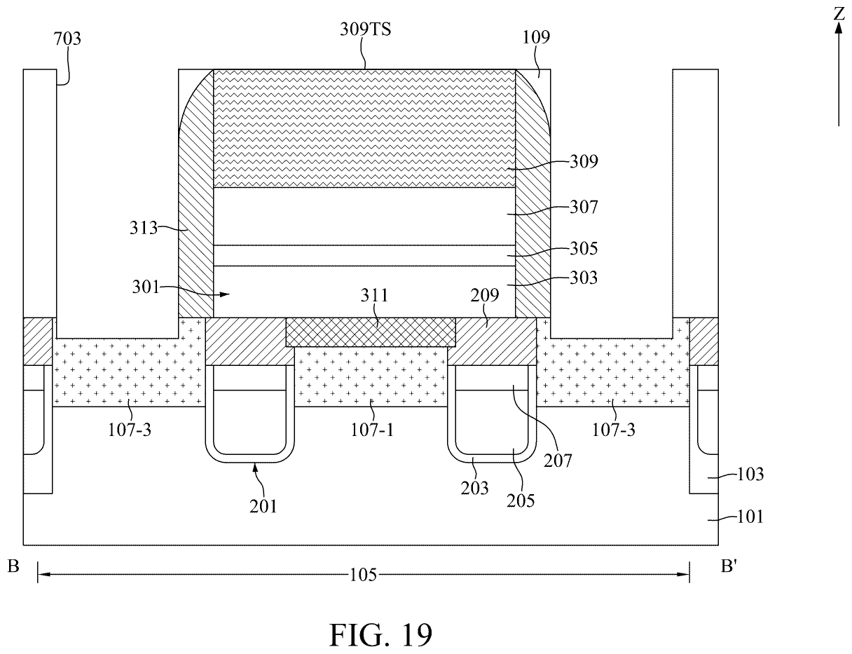

FIG. 17 illustrates, in a schematic top-view diagram, an intermediate semiconductor device in accordance with one embodiment of the present disclosure. FIGS. 18 and 19 are schematic cross-sectional view diagrams along lines A-A′ and B-B′ in FIG. 17, respectively, illustrating part of a process of fabricating the semiconductor device 1A in accordance with one embodiment of the present disclosure.

With reference to FIG. 1 and FIGS. 17 to 19, in step S17, a plurality of capacitor contact openings 703 may be formed in the first dielectric layer 109 and extending to the substrate 101.

With reference to FIGS. 17 to 19, a photolithography process and a subsequent etch process may be performed to form the capacitor contact openings 703 in the first dielectric layer 109 and extending to upper portions of the substrate 101. In some embodiments, a portion of the drain region 107-3 may be exposed through the capacitor contact opening 703. From a top-view perspective, the capacitor contact openings 703 may be located at ends of the active areas 105.

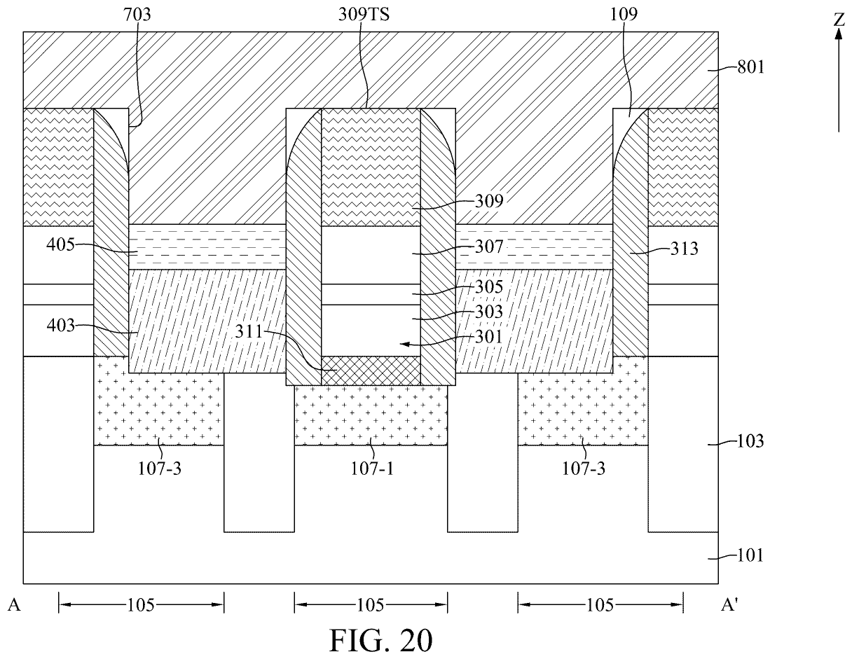

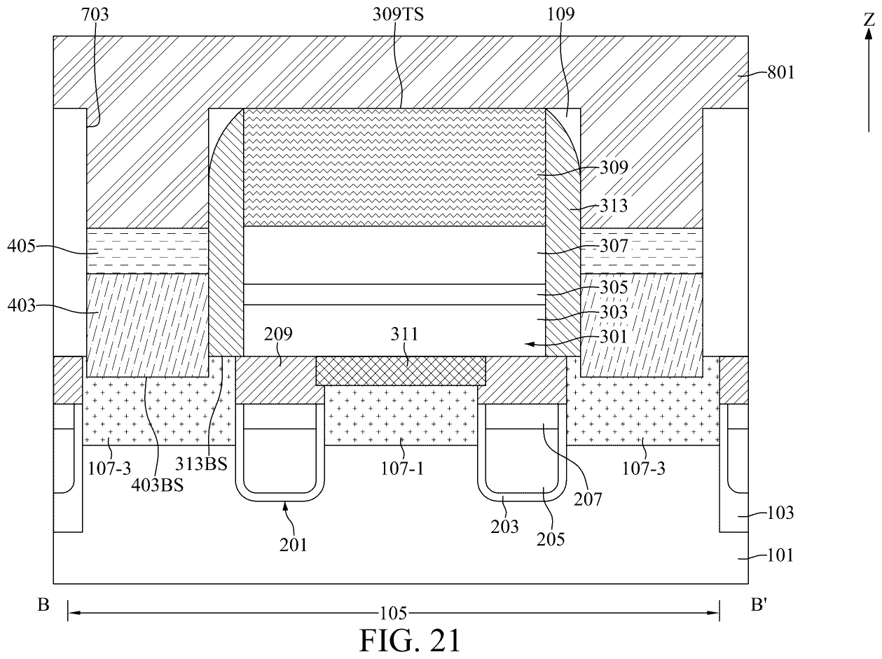

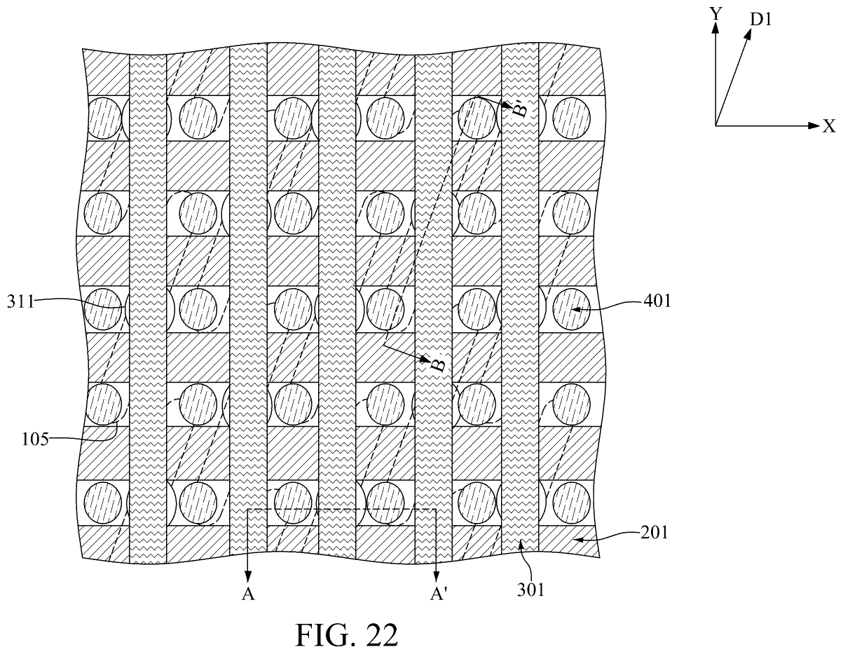

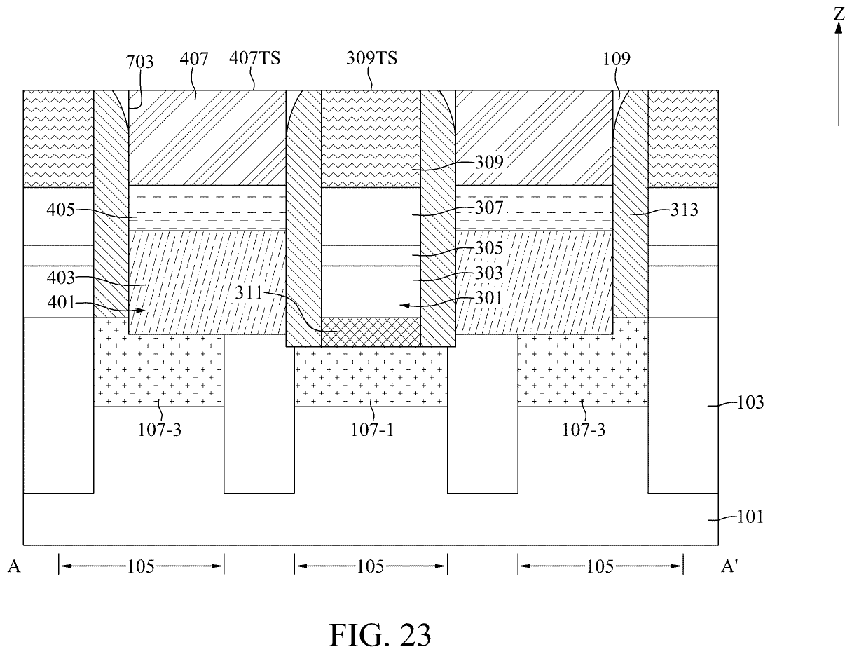

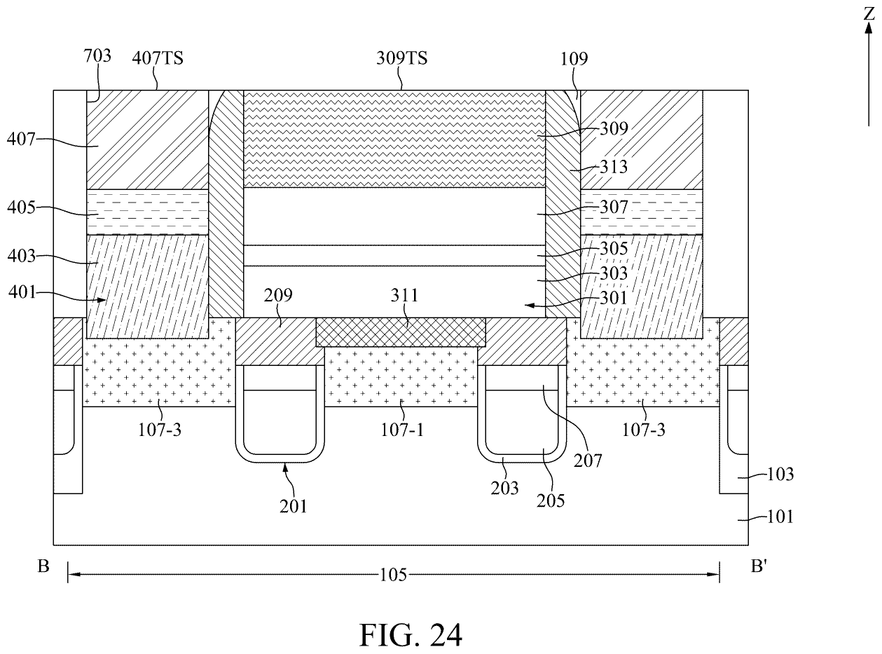

FIGS. 20 and 21 are schematic cross-sectional view diagrams along lines A-A′ and B-B′ in FIG. 17, respectively, illustrating part of a process of fabricating the semiconductor device 1A in accordance with one embodiment of the present disclosure. FIG. 22 illustrates, in a schematic top-view diagram, an intermediate semiconductor device in accordance with one embodiment of the present disclosure. FIGS. 23 and 24 are schematic cross-sectional view diagrams along lines A-A′ and B-B′ in FIG. 22, respectively, illustrating part of a process of fabricating the semiconductor device 1A in accordance with one embodiment of the present disclosure.

With reference to FIG. 1 and FIGS. 20 to 24, in step S19, a capacitor contact structure 401 may be formed in each of the capacitor contact openings 703.

With reference to FIGS. 20 and 21, a capacitor contact bottom conductive layer 403 may be formed in the capacitor contact opening 703. In some embodiments, as shown in FIG. 21, a bottom surface 403BS of the capacitor contact bottom conductive layer 403 may be at a vertical level lower than a vertical level of the bottom surfaces 313BS of the bit line spacers 313. The capacitor contact bottom conductive layer 403 may be formed of, for example, polycrystalline silicon, polycrystalline germanium, or polycrystalline silicon germanium. In some embodiments, the capacitor contact bottom conductive layer 403 may be doped with a dopant such as phosphorus, arsenic, antimony, or boron. In some embodiments, a capacitor contact middle conductive layer 405 may be formed on the capacitor contact bottom conductive layer 403, and in the capacitor contact opening 703. The capacitor contact middle conductive layer 405 may be formed of, for example, cobalt silicide, titanium silicide, nickel silicide, nickel platinum silicide, or tantalum silicide. In some embodiments, a top surface of the capacitor contact middle conductive layer 405 may be at a vertical level lower than a vertical level of the top surface 309TS of the bit line capping layer 309.

A layer of first conductive material 801 may be formed to completely fill the capacitor contact openings 703 and cover the first dielectric layer 109 and the bit line capping layer 309. The first conductive material 801 may be, for example, titanium nitride or tantalum nitride. The capacitor contact middle conductive layer 405 may reduce a contact resistance between the layer of first conductive material 801 and the capacitor contact bottom conductive layer 403.

With reference to FIGS. 22 to 24, a planarization process, such as chemical mechanical polishing, may be performed until the top surface 309TS of the bit line capping layer 309 is exposed to remove excess material, provide a substantially flat surface for subsequent processing steps, and concurrently form a capacitor contact top conductive layer 407 on each of the capacitor contact middle conductive layers 405. In the current stage, top surfaces 407TS of the capacitor contact top conductive layers 407 may be substantially coplanar with the top surface 309TS of the bit line capping layer 309.

The capacitor contact bottom conductive layer 403, the capacitor contact middle conductive layer 405, and the capacitor contact top conductive layer 407 may together form the capacitor contact structure 401. The top surface 407TS of the capacitor contact top conductive layer 407 may be referred to as a top surface of the capacitor contact structure 401. The capacitor contact structure 401 may be electrically coupled to the drain region 107-3.

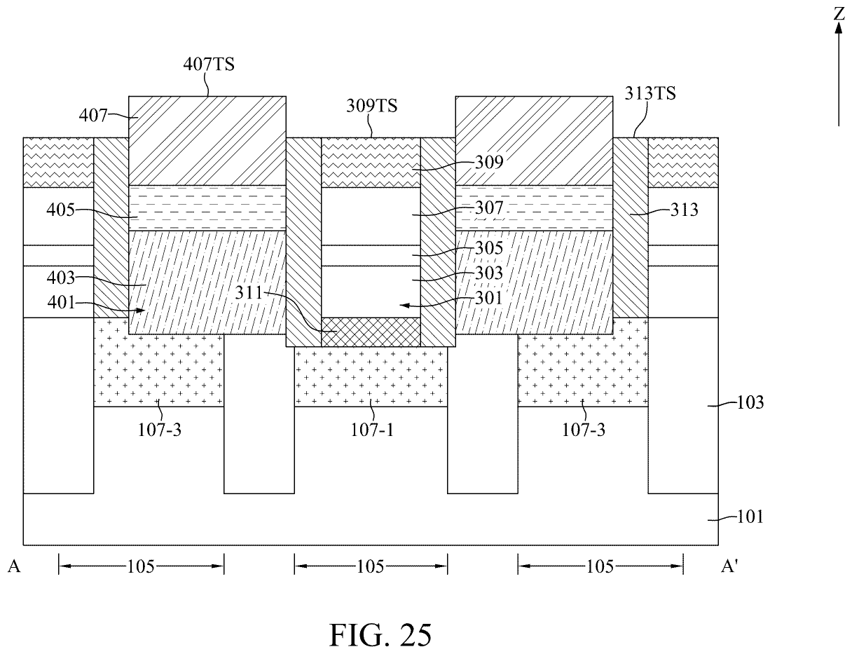

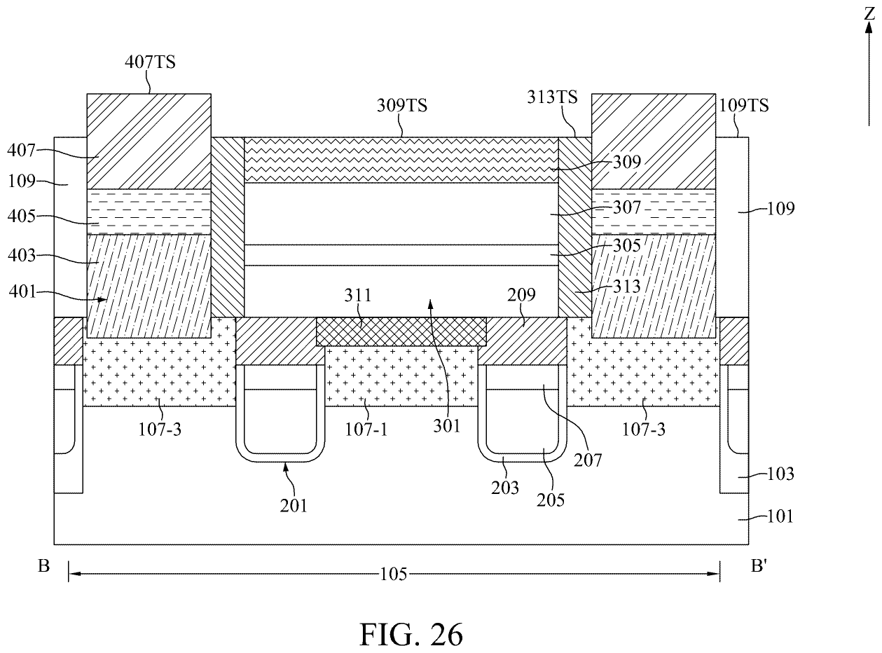

FIGS. 25 and 26 are schematic cross-sectional view diagrams along lines A-A′ and B-B′ in FIG. 22, respectively, illustrating part of a process of fabricating the semiconductor device 1A in accordance with one embodiment of the present disclosure.

With reference to FIGS. 1, 25 and 26, in step S21, the top surface 309TS of the bit line structure 301 (i.e., the top surface 309TS of the bit line capping layer 309) may be recessed.

With reference to FIGS. 25 and 26, a recessing process may be performed to remove portions of the bit line capping layer 309, the first dielectric layer 109, and the bit line spacers 313. The recessing process may be, for example, an isotropic dry etch, an anisotropic dry etch, or a wet etch. During the recessing process, a ratio of an etch rate of the bit line capping layer 309 to an etch rate of the capacitor contact top conductive layer 407 may be between about 100:1 and about 10:1 or between about 20:1 and about 10:1. During the recessing process, a ratio of an etch rate of the first dielectric layer 109 to the etch rate of the capacitor contact top conductive layer 407 may be between about 100:1 and about 10:1 or between about 20:1 and about 10:1. During the recessing process, a ratio of an etch rate of the bit line spacers 313 to the etch rate of the capacitor contact top conductive layer 407 may be between about 100:1 and about 10:1 or between about 20:1 and about 10:1.

After the recessing process is performed, the top surface 309TS of the bit line capping layer 309 may be recessed. In other words, the capacitor contact top conductive layer 407 may protrude from a plane formed by the top surface 309TS of the bit line capping layer 309. The top surface 407TS of the capacitor contact top conductive layer 407 may be at a vertical level higher than a vertical level of the top surface 309TS of the bit line capping layer 309, top surfaces 313TS of the bit line spacers 313, and a top surface 109TS of the first dielectric layer 109. In some embodiments, the top surface 309TS of the bit line capping layer 309, the top surfaces 313TS of the bit line spacers 313, and the top surface of the first dielectric layer 109 may be substantially coplanar.

It should be noted that, in the description of the present disclosure, the term “about,” when used to modify a quantity of an ingredient, component, or reactant of the present disclosure, refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or to carry out the methods, or the like. In one aspect, the term “about” means within 10% of the reported numerical value. In another aspect, the term “about” means within 5% of the reported numerical value. In yet another aspect, the term “about” means within 10%, 9%, 8%, 7%, 6%, 5%, 4%, 3%, 2% or 1% of the reported numerical value.

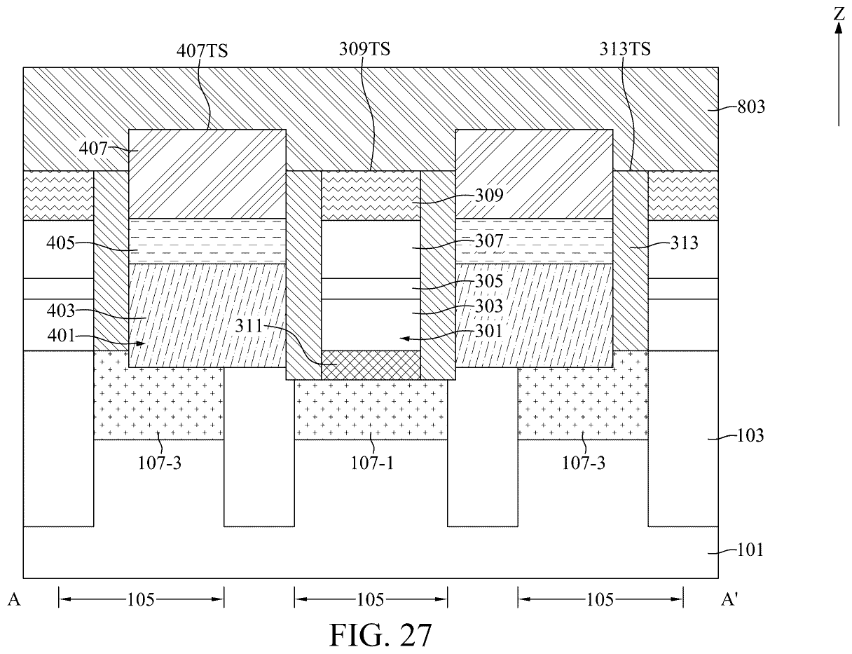

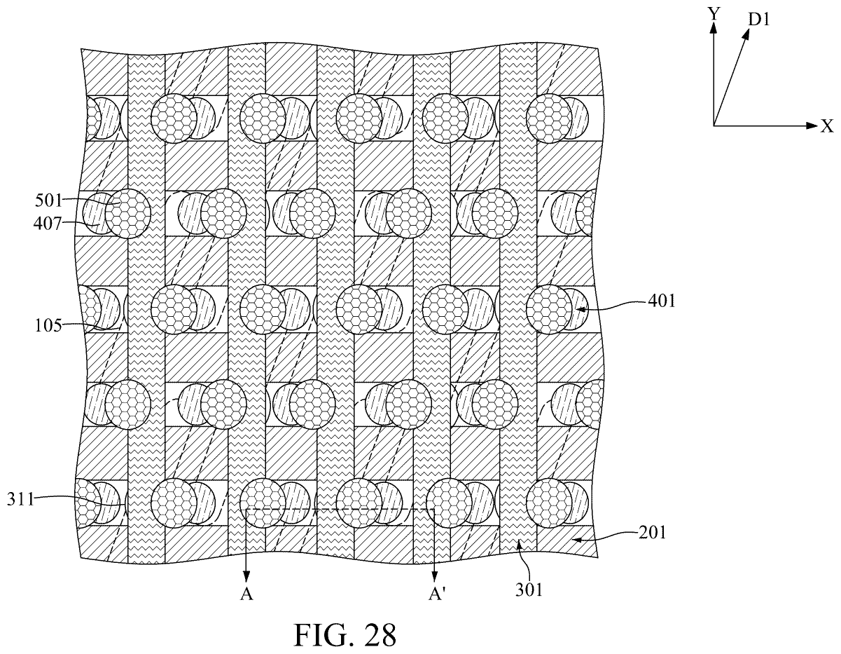

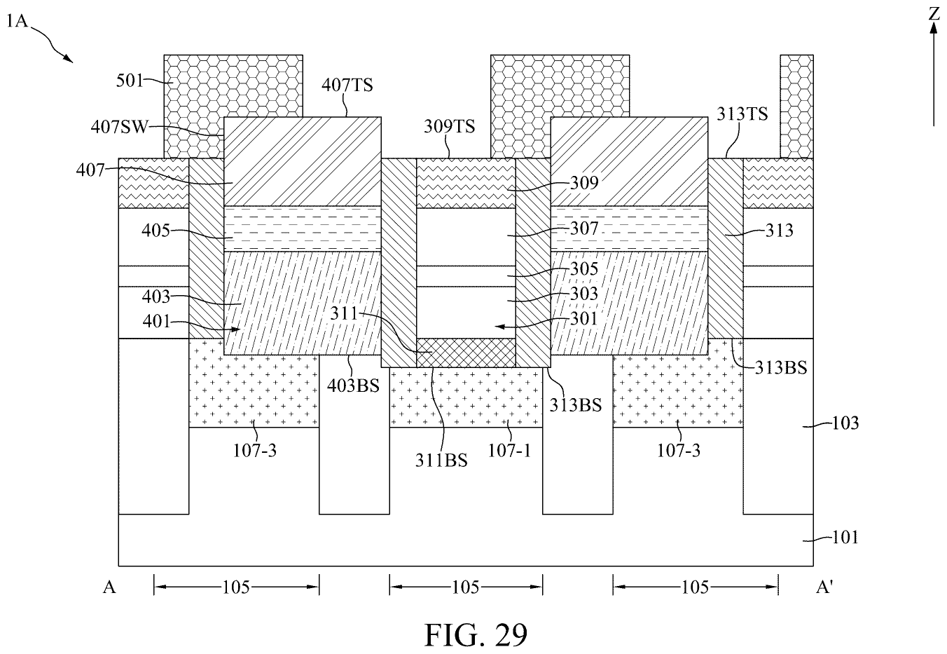

FIG. 27 is a schematic cross-sectional view diagram along line A-A′ in FIG. 22 illustrating part of a process of fabricating the semiconductor device 1A in accordance with one embodiment of the present disclosure. FIG. 28 illustrates, in a schematic top-view diagram, an intermediate semiconductor device in accordance with one embodiment of the present disclosure. FIG. 29 is a schematic cross-sectional view diagram along line A-A′ in FIG. 28 illustrating part of a process of fabricating the semiconductor device 1A in accordance with one embodiment of the present disclosure.

With reference to FIG. 1 and FIGS. 27 to 29, in step S23, a plurality of landing pad layers 501 may be formed partially covering the capacitor contact structures 401.

With reference to FIG. 27, a layer of second conductive material 803 may be formed to cover the capacitor contact top conductive layers 407, the bit line capping layers 309, and the bit line spacers 313. In some embodiments, the layer of second conductive material 803 may be formed of a material having etch selectivity to the capacitor contact top conductive layers 407. In some embodiments, the layer of second conductive material 803 may be, for example, tungsten, copper, or aluminum.

With reference to FIGS. 28 and 29, a photolithography process and a subsequent etch process may be performed to remove portions of the layer of second conductive material 803 and turn the layer of second conductive material 803 into the landing pad layers 501. During the etch process, a ratio of an etch rate of the layer of second conductive material 803 to an etch rate of the capacitor contact top conductive layer 407 may be between about 100:1 and about 10:1 or between about 20:1 and about 10:1.

For convenience of description, only one landing pad layer 501 and one capacitor contact top conductive layer 407 are described. From a cross-sectional perspective, the landing pad layer 501 may cover a portion of the top surface 407TS of the capacitor contact top conductive layer 407 and an upper portion of a sidewall 407SW of the capacitor contact top conductive layer 407. In other words, the landing pad layer 501 may partially cover the capacitor contact top conductive layer 407. From a top-view perspective, the landing pad layer 501 may be offset from the capacitor contact top conductive layer 407.

The partial covering of the capacitor contact top conductive layer 407 by the landing pad layer 501 may increase a contact surface between the landing pad layer 501 and the capacitor contact top conductive layer 407. Accordingly, a resistance between the landing pad layer 501 and the capacitor contact top conductive layer 407 may be reduced. As a result, power consumption of the semiconductor device 1A may be reduced. In addition, the protruding capacitor contact top conductive layer 407 may provide sufficient support for the landing pad layer 501.

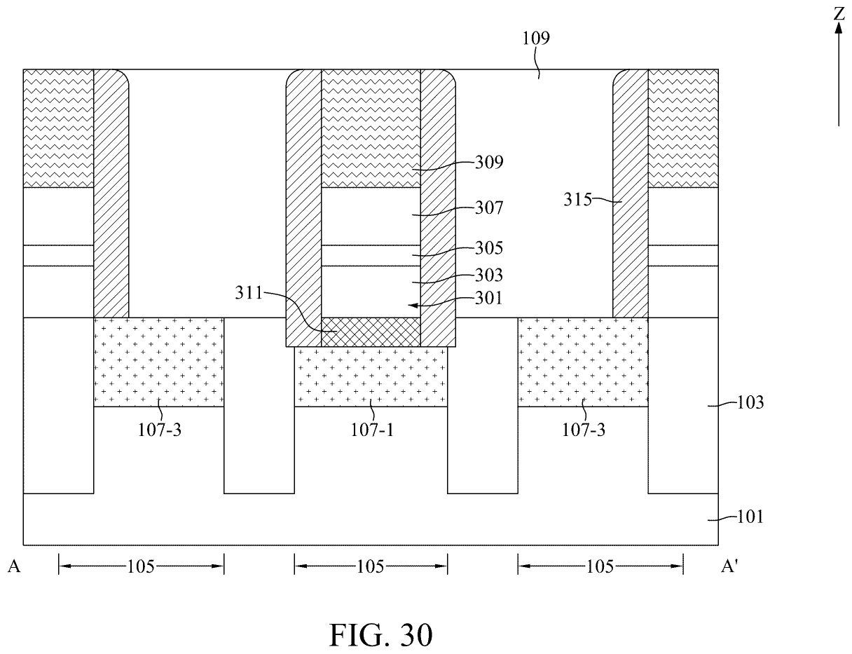

FIGS. 30 to 34 are schematic cross-sectional view diagrams along line A-A′ in FIG. 12 illustrating part of a process of fabricating a semiconductor device 1B in accordance with another embodiment of the present disclosure.

With reference to FIG. 30, an intermediate semiconductor device similar to that shown in FIG. 13 may be provided. A plurality of sacrificial spacers 315 may be formed by a procedure similar to that of the formation of the bit line spacers 313 illustrated in FIG. 13. In some embodiments, the sacrificial spacers 315 may be formed of a material having etch selectivity to the bit line capping layers 309 and the first dielectric layer 109. In some embodiments, the sacrificial spacers 315 may be formed of, for example, an energy-removable material such as a thermal decomposable material, a photonic decomposable material, an e-beam decomposable material, or a combination thereof. The first dielectric layer 109 may be formed by a procedure similar to that illustrated in FIG. 15.

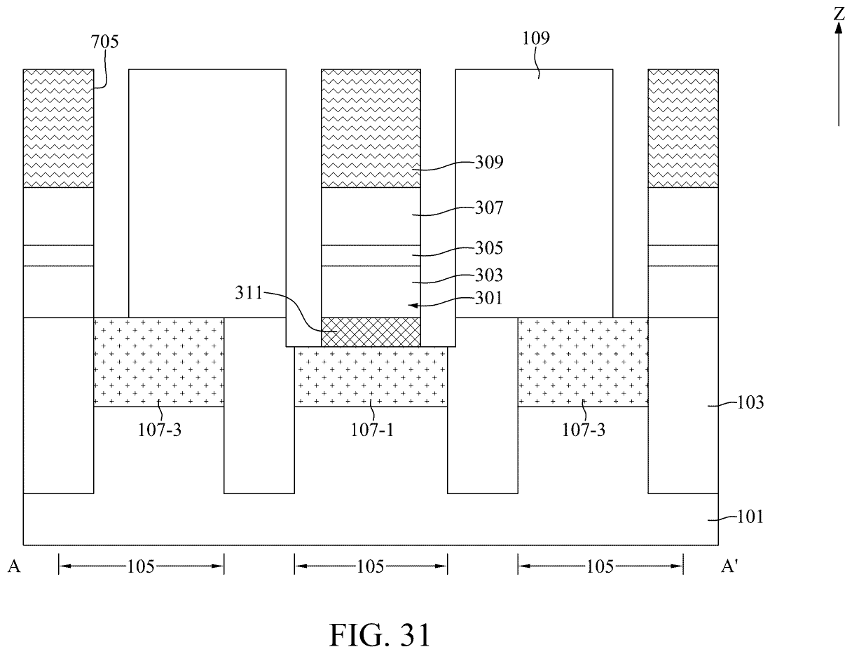

With reference to FIG. 31, in some embodiments, another planarization process may be applied to the intermediate semiconductor device illustrated in FIG. 30 to expose top surfaces of the sacrificial spacers 315. In some embodiments, the planarization process for the first dielectric layer 109 may be performed until the top surfaces of the sacrificial spacers 315 are exposed. Subsequently, a removal process may be performed to remove the sacrificial spacers 315. After the removal process is performed, first trenches 705 may be formed in places previously occupied by the sacrificial spacers 315.

In some embodiments, the removal process may be an etch process such as a dry etch or a wet etch. During the etch process, a ratio of an etch rate of the sacrificial spacer 315 to an etch rate of the first dielectric layer 109 may be between about 100:1 and about 10:1 or between about 20:1 and about 10:1. During the etch process, a ratio of the etch rate of the sacrificial spacers 315 to an etch rate of the bit line capping layer 309 may be between about 100:1 and about 10:1 or between about 20:1 and about 10:1.

In some embodiments, an energy treatment may be applied to remove the sacrificial spacers 315 formed of the energy-removable material. The energy treatment may be performed by applying an energy source to the intermediate semiconductor device shown in FIG. 30. The energy source may include heat, light, or a combination thereof. When heat is used as an energy source, a temperature of the energy treatment may be between about 800° C. and about 900° C. When light is used as an energy source, an ultraviolet light may be applied.

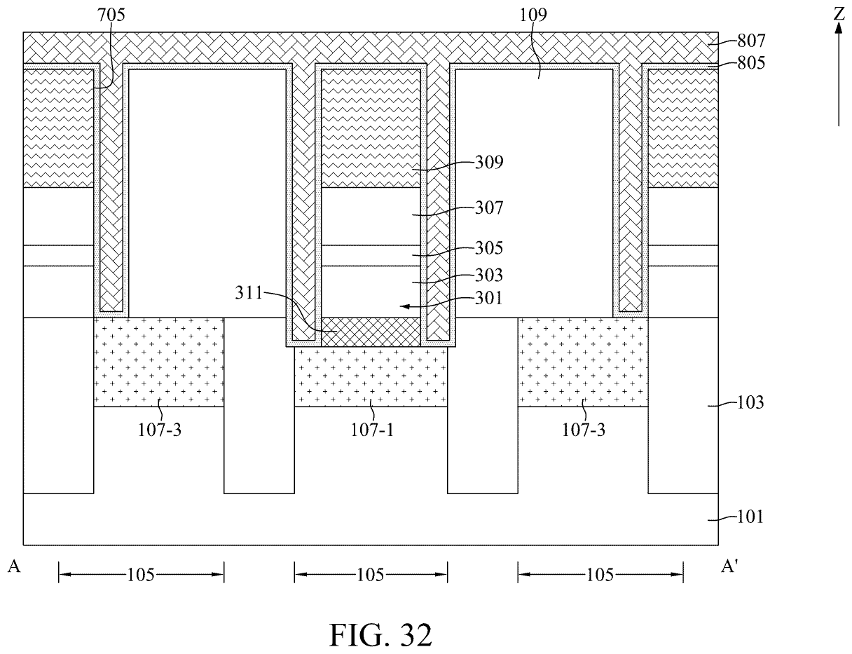

With reference to FIG. 32, a layer of first insulating material 805 may be conformally formed in the first trenches 705 and may cover the first dielectric layer 109 and the bit line capping layers 309. A layer of second insulating material 807 may be formed on the layer of first insulating material 805 and may completely fill the first trenches 705.

In some embodiments, the first insulating material 805 may be, for example, silicon nitride, boron nitride, silicon boron nitride, phosphorus boron nitride, or boron carbon silicon nitride. In some embodiments, the second insulating material 807 may be, for example, silicon oxide.

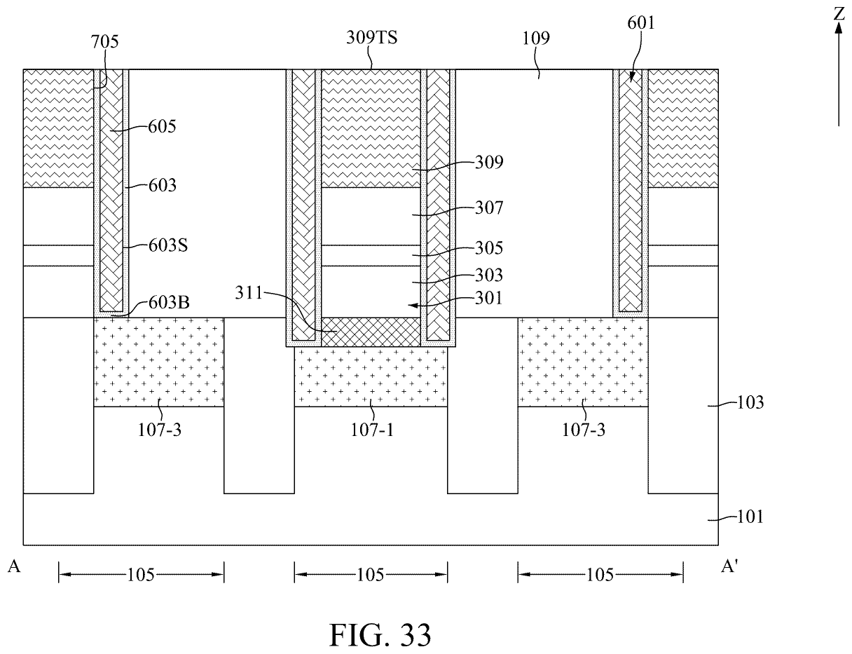

With reference to FIG. 33, a planarization process, such as chemical mechanical polishing, may be performed until top surfaces of the bit line capping layers 309 are exposed to remove excess material and provide a substantially flat surface for subsequent processing steps. After the planarization process is performed, the layer of first insulating material 805 may be turned into a plurality of first insulating layers 603. The layer of second insulating material 807 may be turned into a plurality of second insulating layers 605. The first insulating layers 603 and the second insulating layers 605 together form insulation structures 601.

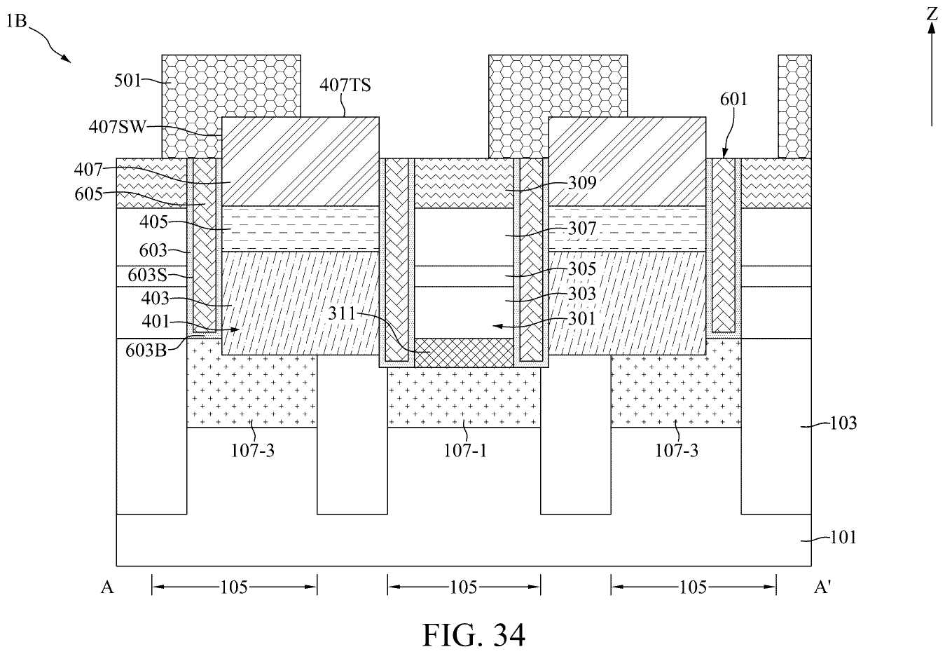

For convenience of description, only one insulation structure 601 is described. The first insulating layer 603 may have a U-shaped cross-sectional profile. The first insulating layer 603 may include a bottom portion 603B and two side portions 603S. The bottom portion 603B may be linear and may be horizontally disposed on the substrate 101, specifically on the drain region 107-3. The two side portions 603S may be linear and may each be connected to an end of the bottom portion 603B. One of the two side portions 603S may be attached to a sidewall of the bit line structure 301 and another one of the two side portions 603S may be attached to a sidewall of the capacitor contact structure 401 as shown in FIG. 34. The second insulating layer 605 may be disposed within a space formed by the bottom portion 603B and the two side portions 603S. In some embodiments, the bottom portion 603B may be horizontally disposed in the substrate 101 and on the source region 107-1. One of the two side portions 603S may be attached to a sidewall of the capacitor contact structure 401 and another one of the two side portions may be attached to a sidewall of the bit line contact 311.

With reference to FIG. 34, the capacitor contact structure 401 may be formed by a procedure similar to that illustrated in FIGS. 17 to 24. The recessing process may be performed by a procedure similar to that illustrated in FIG. 25. The landing pad layers 501 may be formed by a procedure similar to that illustrated in FIGS. 27 to 29. Some of the landing pad layers 501 may cover one of the insulation structures 601.

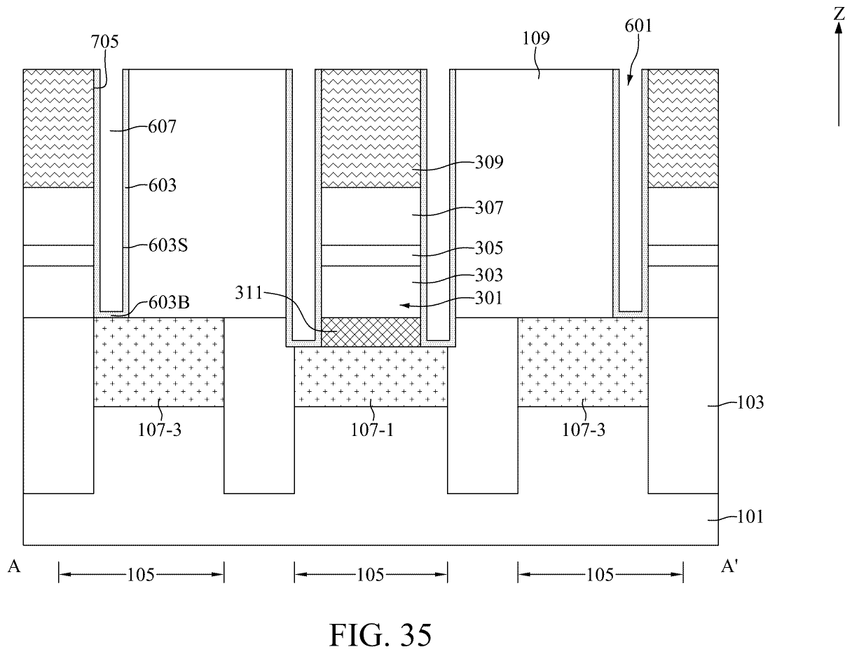

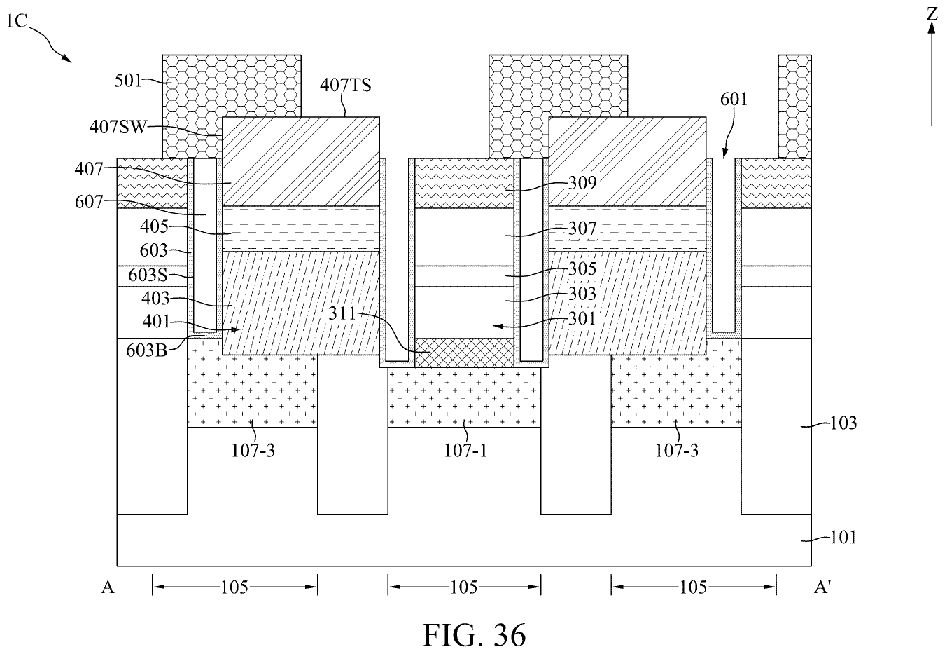

FIGS. 35 and 36 are schematic cross-sectional view diagrams along line A-A′ in FIG. 12 illustrating part of a process of fabricating a semiconductor device 1C in accordance with another embodiment of the present disclosure.

With reference to FIG. 35, an intermediate semiconductor device shown in FIG. 33 may be provided. A removal process may be performed to remove the second insulating layers 605. Air gaps 607 may be concurrently formed in places previously occupied by the second insulating layers 605. Specifically, each air gap 607 may comprise a space formed by the bottom portion 603B and the two side portions 603S. The first insulating layer 603 and the air gap 607 may together form the insulation structure 601. The air gap 607 may reduce a parasitic capacitance between the capacitor contact structure 401 and the bit line structure 301. As a result, performance of the semiconductor device 1C may be improved.

In some embodiments, the second insulating layer 605 may be formed of a material having etch selectivity to the first insulating layer 603. The removal process may be an etch process such as a dry etch or a wet etch. During the etch process, a ratio of an etch rate of the second insulating layer 605 to an etch rate of the first insulating layer 603 may be between about 100:1 and about 10:1 or between about 20:1 and about 10:1. During the etch process, a ratio of the etch rate of the second insulating layer 605 to an etch rate of the first dielectric layer 109 may be between about 100:1 and about 10:1 or between about 20:1 and about 10:1. During the etch process, a ratio of the etch rate of the second insulating layer 605 to an etch rate of the bit line capping layer 309 may be between about 100:1 and about 10:1 or between about 20:1 and about 10:1.

In some embodiments, the second insulating layer 605 may be formed of, for example, an energy-removable material such as a thermal decomposable material, a photonic decomposable material, an e-beam decomposable material, or a combination thereof. The removal process may apply an energy treatment to remove the second insulating layer 605. The energy treatment may be performed by applying an energy source to the second insulating layer 605. The energy source may include heat, light, or a combination thereof. When heat is used as an energy source, a temperature of the energy treatment may be between about 800° C. and about 900° C. When light is used as an energy source, an ultraviolet light may be applied.

With reference to FIG. 36, a plurality of capacitor contact structures 401 may be formed by a procedure similar to that illustrated in FIGS. 17 to 24. A recessing process may be performed by a procedure similar to that illustrated in FIG. 25. A plurality of landing pad layers 501 may be formed by a procedure similar to that illustrated in FIGS. 17 to 29. The landing pad layers 501 may cover some of the insulation structures 601.

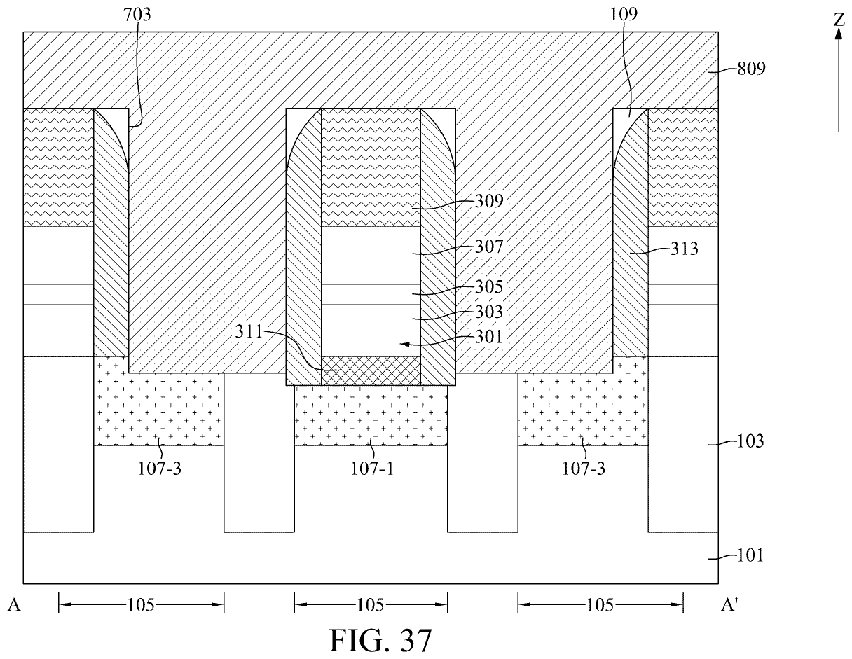

FIGS. 37 to 39 are schematic cross-sectional view diagrams along line A-A′ in FIG. 17 illustrating part of a process of fabricating a semiconductor device 1D in accordance with another embodiment of the present disclosure.

With reference to FIG. 37, an intermediate semiconductor device shown in FIG. 18 may be provided. A layer of third conductive material 809 may be formed to completely fill the capacitor contact openings 703 and cover the bit line structure 301 and the first dielectric layer 109. The third conductive material 809 may be, for example, polycrystalline silicon, polycrystalline germanium, or polycrystalline silicon germanium.

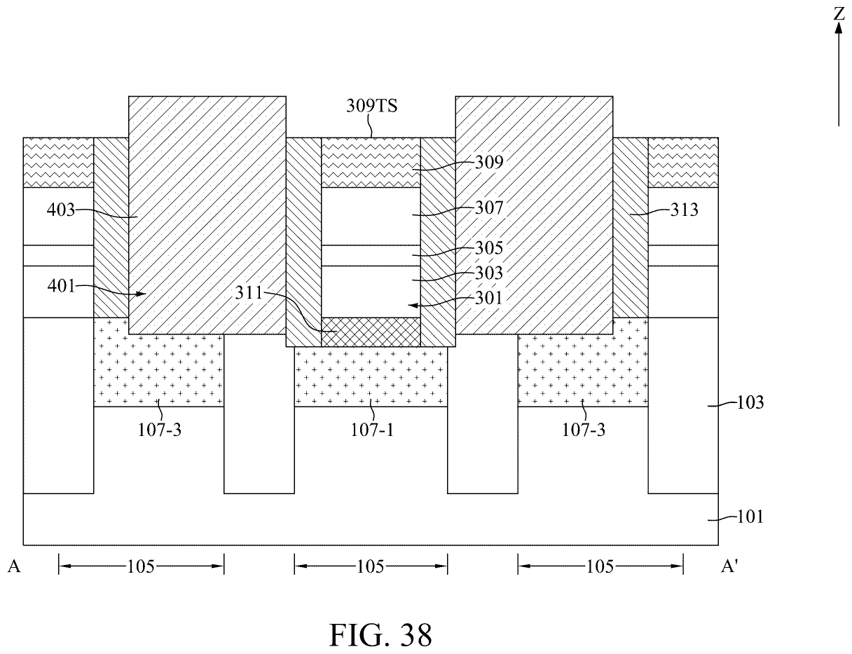

With reference to FIG. 38, a procedure similar to that illustrated in FIGS. 22 to 25 may be performed on the layer of third conductive material 809. The layer of third conductive material 809 may be turned into a plurality of capacitor contact structures 401. Each capacitor contact structure 401 may include a capacitor contact bottom conductive layer 403 formed of polycrystalline silicon, polycrystalline germanium, or polycrystalline silicon germanium. The capacitor contact bottom conductive layer 403 may protrude from a plane formed by the top surfaces 309TS of the bit line capping layers 309.

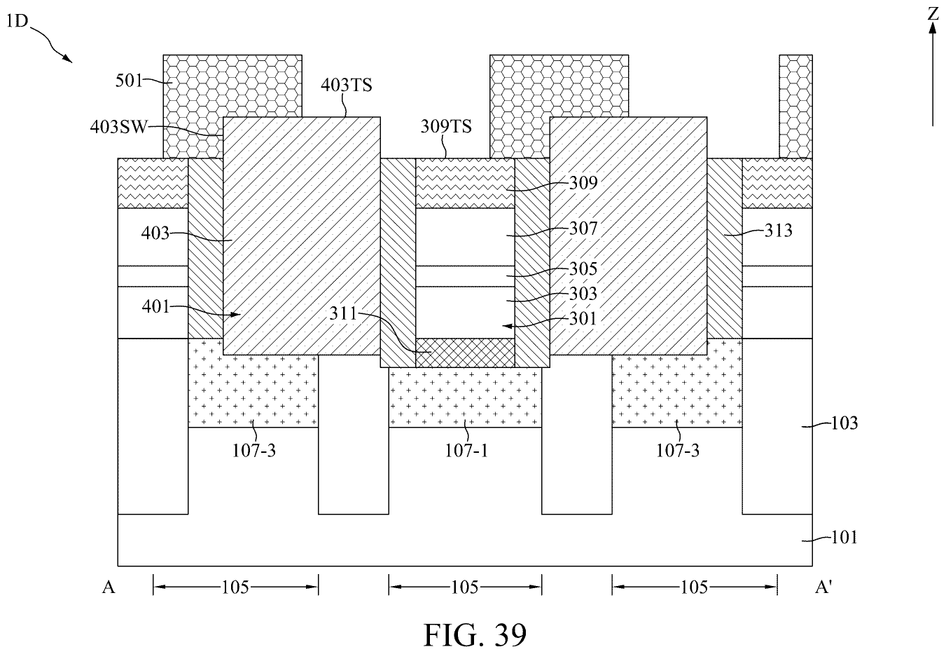

With reference to FIG. 39, a plurality of landing pad layers 501 may be formed by a procedure similar to that illustrated in FIGS. 27 to 29. The landing pad layer 501 may partially cover the capacitor contact bottom conductive layer 403. Specifically, the landing pad layer 501 may cover a portion of a top surface 403TS of the capacitor contact bottom conductive layer 403 and an upper portion of a sidewall 403SW of the capacitor contact bottom conductive layer 403.

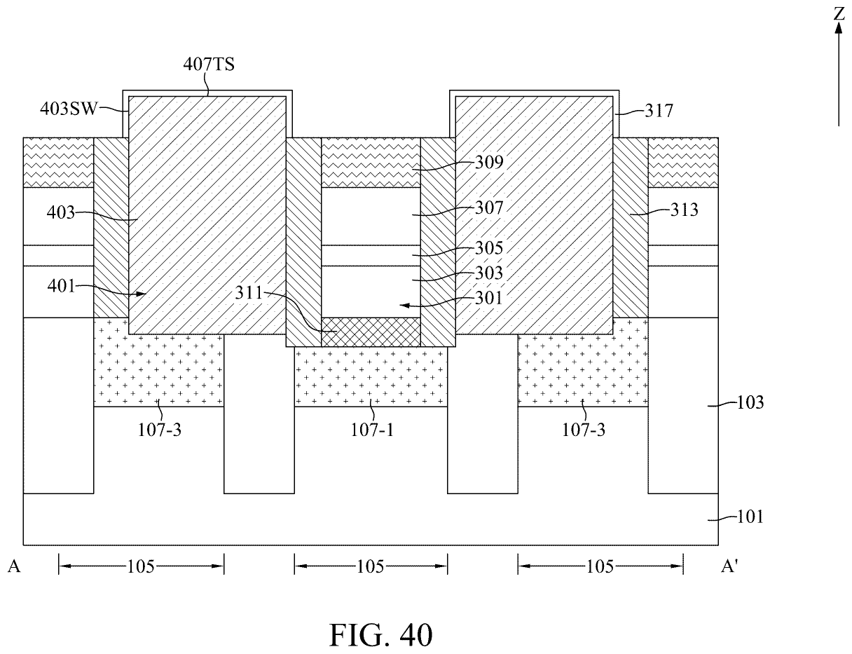

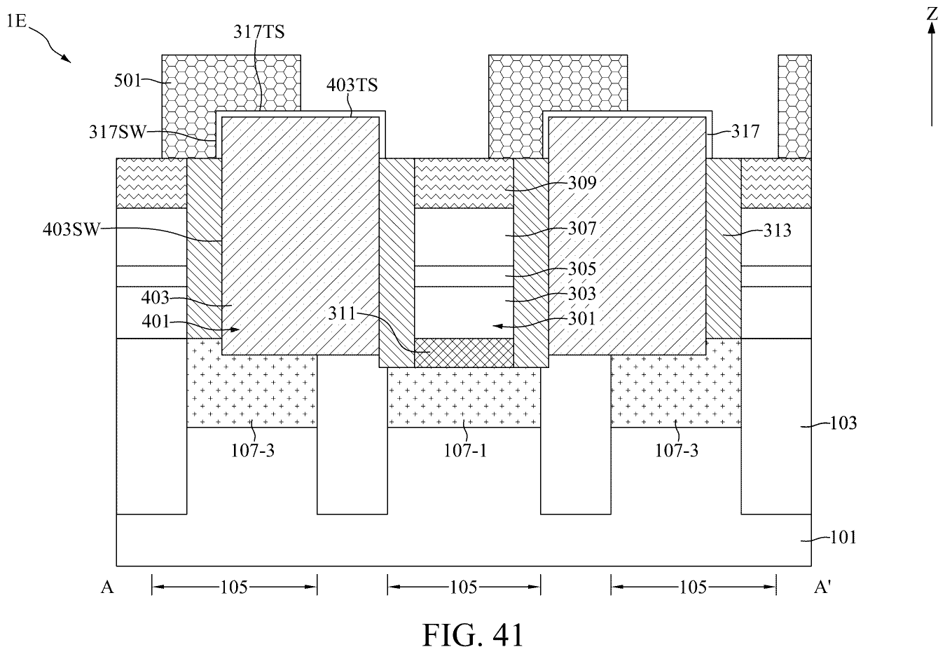

FIGS. 40 and 41 are schematic cross-sectional view diagrams along line A-A′ in FIG. 17 illustrating part of a process of fabricating a semiconductor device 1E in accordance with another embodiment of the present disclosure.

With reference to FIG. 40, an intermediate semiconductor device shown in FIG. 38 may be provided. Subsequently, a layer of conductive material may be formed over the intermediate semiconductor device. The conductive material may include, for example, titanium, nickel, platinum, tantalum, or cobalt. In some embodiments, a thermal treatment may be performed. During the thermal treatment, metal atoms of the layer of conductive material may react chemically with silicon atoms of the capacitor contact bottom conductive layer 403 to form an adjustment layer 317. The adjustment layer 317 may include titanium silicide, nickel silicide, nickel platinum silicide, tantalum silicide, or cobalt silicide. In some embodiments, the thermal treatment may be a dynamic surface annealing process. After the thermal treatment is performed, a cleaning process may be performed to remove unreacted conductive material. The cleaning process may use an etchant such as hydrogen peroxide and an SC-1 solution.

The adjustment layers 317 may have a thickness between about 2 nm and about 20 nm. Each of the adjustment layers 317 may cover a top surface 403TS of the capacitor contact bottom conductive layer 403 and upper portions of sidewalls 403SW of the capacitor contact bottom conductive layer 403.

With reference to FIG. 41, a plurality of landing pad layers 501 may be formed by a procedure similar to that illustrated in FIGS. 27 to 29. The landing pad layer 501 may partially cover the adjustment layer 317. Specifically, the landing pad layer 501 may cover a portion of a top surface 317TS of the adjustment layer 317 and one of sidewalls 317SW of the adjustment layer 317.

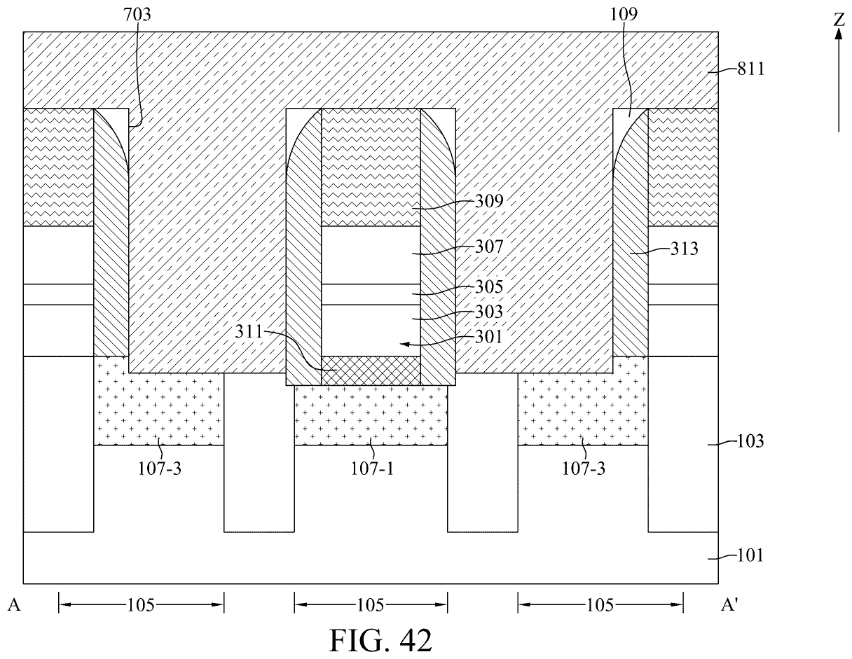

FIGS. 42 to 44 are schematic cross-sectional view diagrams along line A-A′ in FIG. 17 illustrating part of a process of fabricating a semiconductor device 1F in accordance with another embodiment of the present disclosure.

With reference to FIG. 42, an intermediate semiconductor device shown in FIG. 18 may be provided. A layer of fourth conductive material 811 may be formed to completely fill the capacitor contact openings 703 and cover the bit line structures 301 and the first dielectric layer 109. The fourth conductive material 811 may be, for example, titanium nitride or tantalum nitride.

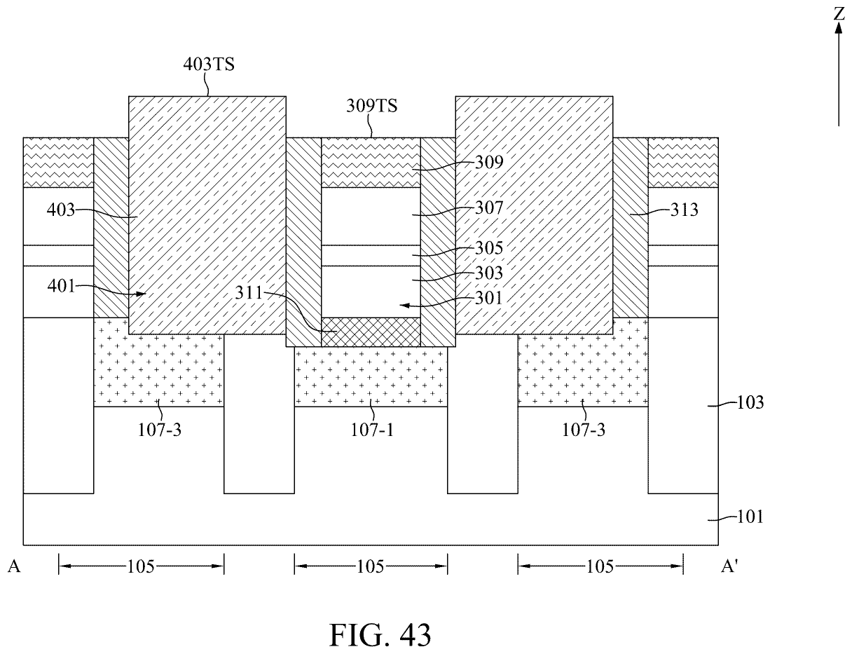

With reference to FIG. 43, a procedure similar to that illustrated in FIGS. 22 to 25 may be performed on the layer of fourth conductive material 811. The layer of fourth conductive material 811 may be turned into a plurality of capacitor contact structures 401. Each of the capacitor contact structures 401 may include a capacitor contact bottom conductive layer 403 formed of titanium nitride or tantalum nitride. The capacitor contact bottom conductive layer 403 may protrude from a plane formed by top surfaces 309TS of the bit line capping layers 309.

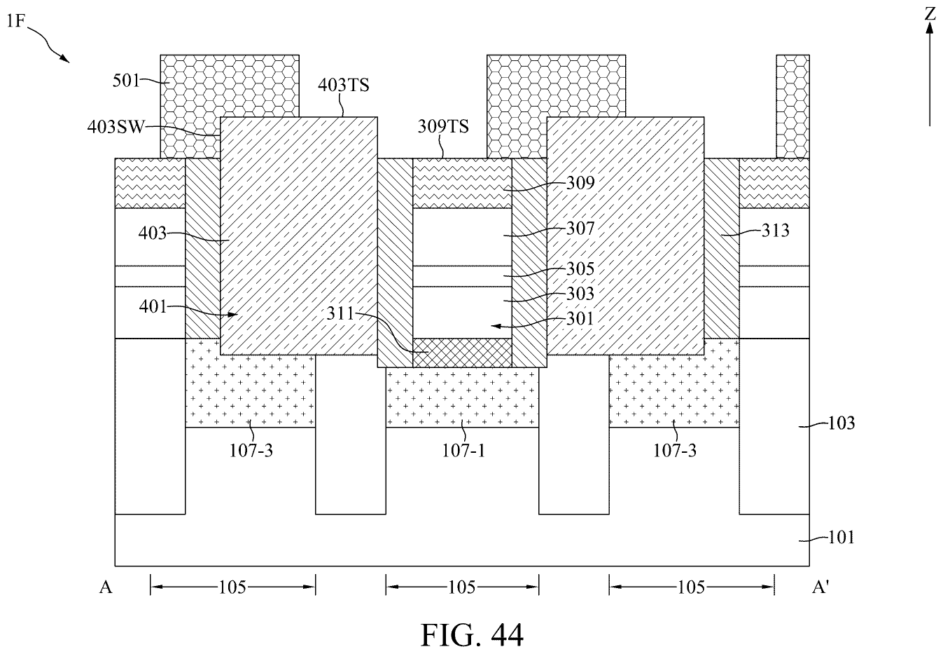

With reference to FIG. 44, a plurality of landing pad layers 501 may be formed by a procedure similar to that illustrated in FIGS. 27 to 29. The landing pad layer 501 may partially cover the capacitor contact bottom conductive layer 403. Specifically, the landing pad layer 501 may cover a portion of a top surface 403TS of the capacitor contact bottom conductive layer 403 and an upper portion of a sidewall 403SW of the capacitor contact bottom conductive layer 403.

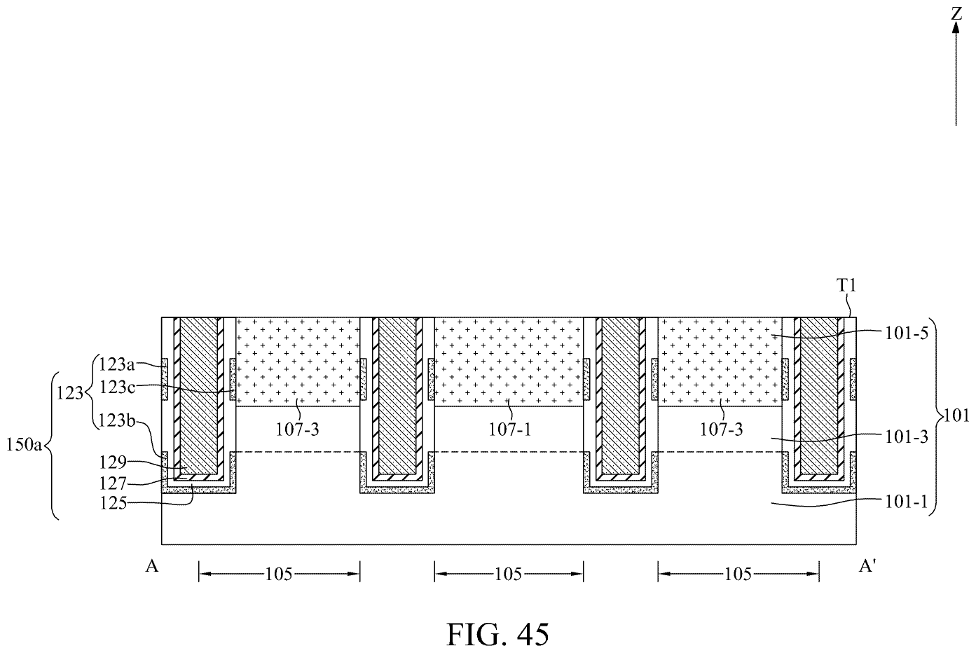

FIGS. 45 to 48 are schematic cross-sectional view diagrams along line A-A′ in FIG. 17 illustrating part of a process of fabricating a semiconductor device 1G in accordance with another embodiment of the present disclosure.

With reference to FIG. 45, in some embodiments, a substrate 101 may be provided. The substrate 101 in FIG. 45 may be same as or similar to the substrate 101 in FIGS. 2 to 4 except that the substrate 101 in FIG. 45 may be a silicon-on-insulator substrate and may comprise a plurality of shallow trench isolation (STI) structures 150a. From a cross-sectional perspective along line A-A′ in FIG. 2, as mentioned above, when the substrate 101 is formed of silicon-on-insulator, the substrate 101 may include a top semiconductor layer 101-5 and a bottom semiconductor layer 101-1 formed of silicon, and a buried insulating layer 101-3 which may separate the top semiconductor layer 101-5 from the bottom semiconductor layer 101-1. The buried insulating layer 101-3 may include, for example, a crystalline oxide, a non-crystalline oxide, a nitride, or a combination thereof.

The STI structure 150a may comprise a first liner 123, a second liner 125 disposed over the first liner 123, a third liner 127 disposed over the second liner 125, and a trench-filling layer 129 disposed over the third liner 127 and separated from the second liner 125 by the third liner 127. The first liner 123 may contact the top semiconductor layer 101-5 and the bottom semiconductor layer 101-1. The second liner 125 may cover the first liner 123 and may contact the buried insulating layer 101-3. The third liner 127 may cover the second liner 125. In particular, in some embodiments, the first liner 123 has portions 123a and 123c covering opposite sidewalls of the silicon layer 105, and a portion 123b separating the second liner 125 from the bottom semiconductor layer 101-1 of the semiconductor substrate 101.

It should be noted that the portions 123a, 123b and 123c of the first liner 123 are separated from each other.

In some embodiments, the first liner 123, the second liner 125 and the third liner 127 of the STI structure 150a are made of different materials. For example, the first liner 123 is made of silicon oxide, the second liner 125 is made of nitride, and the third liner 127 is made of silicon oxynitride. In some embodiments, the STI structure 150a may penetrate through the top semiconductor layer 101-5 and the buried insulating layer 101-3 and extend into the bottom semiconductor layer 101-1.

As shown in FIG. 45, after formation of the STI structures 150a, source/drain regions 107-1 and 107-3 may be formed in upper portions of the active areas 105 by a procedure similar to that used to form the source/drain regions 107-1 and 107-3 as shown in in FIGS. 7 and 8, and detailed descriptions are not repeated.

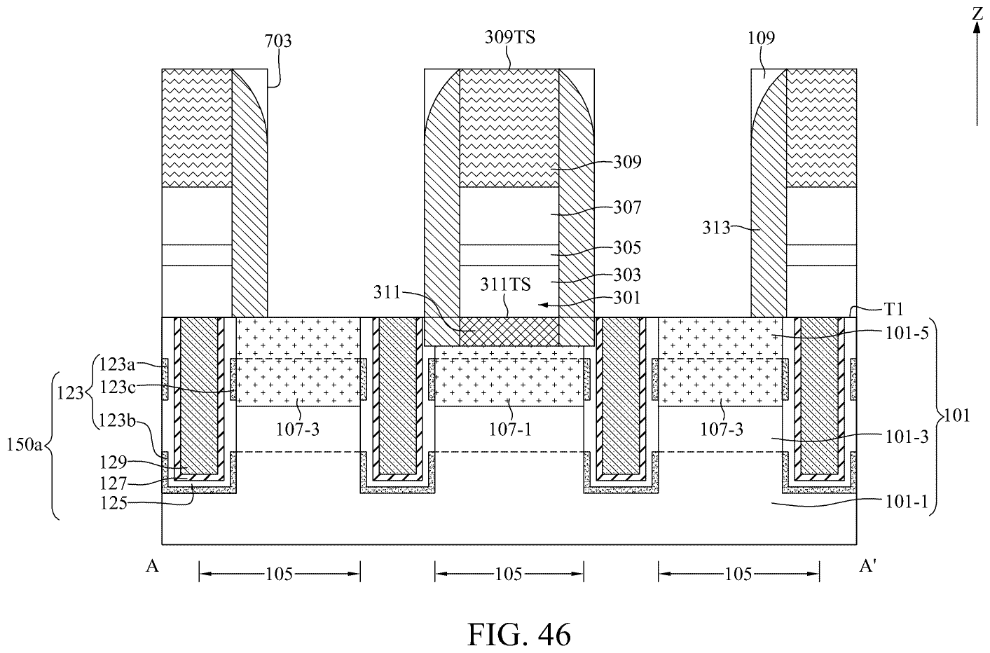

With reference to FIG. 46, a plurality of bit line structures 301, a plurality of bit line contacts 311, a plurality of bit line spacers 313 and a plurality of capacitor contact openings 703 may be formed by a procedure similar to that of the bit line structures 301, the bit line contacts 311, the bit line spacers 313 and the capacitor contact openings 703 shown in FIGS. 9 to 18, and details thereof are not repeated.

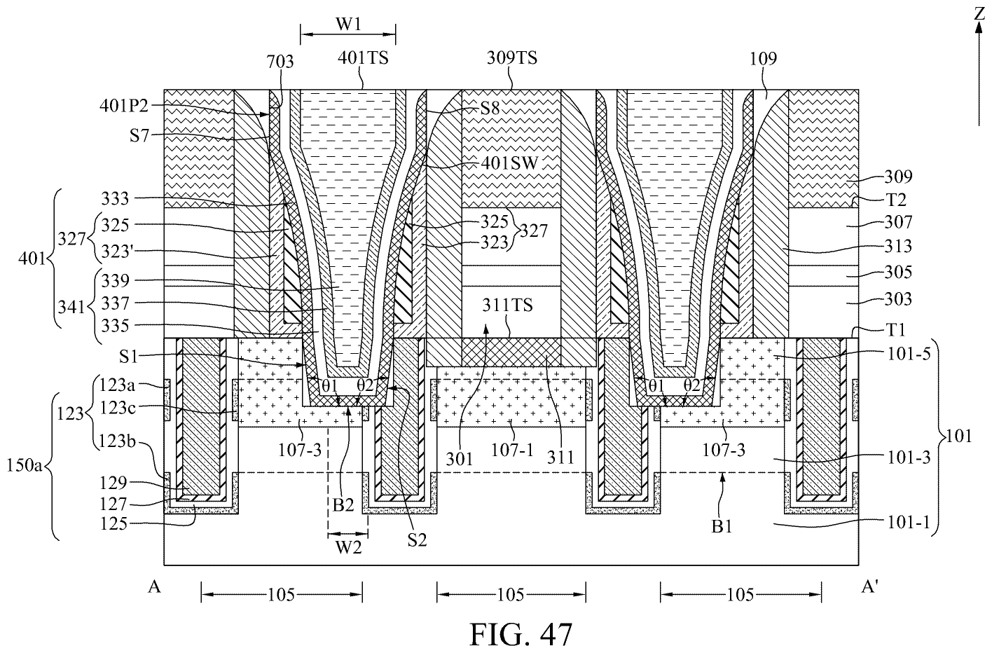

With reference to FIG. 47, a plurality of capacitor contact structures 401 may be formed next to the bit line structures 301. The capacitor contact structure 401 may be disposed in the substrate 101 and may protrude from the substrate. In some embodiments, the capacitor contact structure 401 may comprise a liner layer 333 disposed on the substrate 101 and extending into the substrate 101, a capacitor conductive structure 341 disposed over and surrounded by the liner layer 333, and a spacer structure 327 surrounding the capacitor conductive structure 341 and separated from the capacitor conductive structure 341 by the liner layer 333.

In some embodiments, the capacitor conductive structure 341 includes a barrier layer 335 conformally disposed over and surrounded by the liner layer 333, a metal layer 337 disposed over and surrounded by the barrier layer 335, and a metal filling portion 339 disposed over and surrounded by the metal layer 337. In some embodiments, the capacitor conductive structure 341 is surrounded by the spacer structure 327.

In some embodiments, the metal filling portion 339 of the capacitor conductive structure 341 has a tapered profile with a bottom portion of the metal filling portion 339 being narrower than a respective top portion of the metal filling portion 339. For example, the metal filling portion 339 has a top width W1 and a bottom width W2, wherein the top width W1 is greater than the bottom width W2. In some embodiments, the capacitor conductive structure 341 has a tapered profile with a bottom portion of the capacitor conductive structure 341 being narrower than a respective top portion of the capacitor conductive structure 341.

Moreover, in some embodiments, the capacitor conductive structure 341 penetrates through the capacitor contact opening 703 and extends into an upper portion of the substrate 101 (i.e., the top semiconductor layer 101-5) and a portion of one of the STI structures 150a. In some embodiments, the capacitor conductive structure 341 is separated from the substrate 101 and the spacer structure 327 by the liner layer 333. In some embodiments, the metal layer 337 of the capacitor conductive structure 341 includes copper-manganese (Cu—Mn) alloy, and the metal filling portion 339 of the capacitor conductive structure 341 includes copper (Cu).

In some embodiments, the spacer structure 327 may be disposed in the capacitor contact opening 703. In some embodiments, the spacer structure 327 is disposed over and in direct contact with a top surface T1 of the substrate 101. In some embodiments, the spacer structure 327 includes an L-shaped liner 323′ and a porous low-k dielectric layer 325 disposed over the L-shaped liner 323′. In some embodiments, a top portion of the L-shaped liner 323′ protrudes from a top surface T2 of the bit line top conductive layer 307.

In some embodiments, the liner layer 333 may cover the spacer structure 327. In some embodiments, the liner layer 333 is disposed within the capacitor contact opening 703 and extends into the substrate 101 and into one of the STI structures 150a. In some embodiments, vertical sidewalls S7 and S8 of the liner layer 333 are in direct contact with the first dielectric layer 109. In addition, in some embodiments, the liner layer 333 is in direct contact with the spacer structure 327. As shown in FIG. 47, in some embodiments, a bottom surface B2 of the liner layer 333 is lower than the top surface T1 of the substrate 101, and the bottom surface B2 of the liner layer 333 is higher than a bottom surface B1 of the buried insulating layer 101-3.

Moreover, in some embodiments, the liner layer 333 has tapered sidewalls S1 and S2 in direct contact with the substrate 101 (i.e., the top semiconductor layer 101-5) and one of the STI structures 150a. As shown in FIG. 47, the liner layer 333 includes an angle θ1 between the sidewall S1 and the bottom surface B2, and another angle θ2 between the sidewall S2 and the bottom surface B2. In some embodiments, each of the angles θ1 and θ2 is greater than 90 degrees. In some embodiments, the porous low-k dielectric layer 325 is enclosed by the liner layer 333 and the L-shaped liner 323′ of the spacer structure 327.

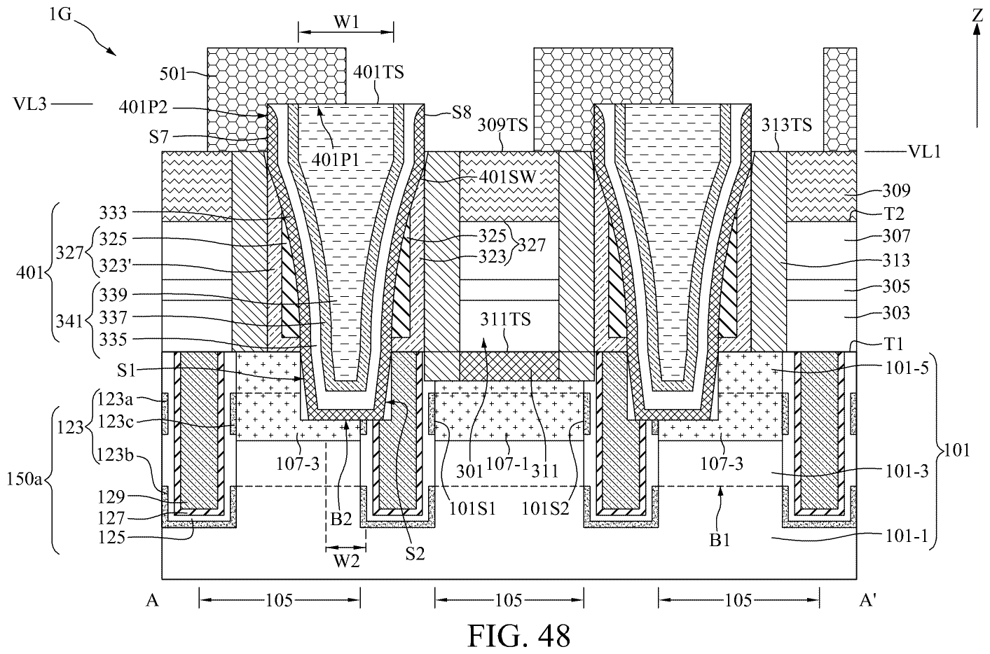

With reference to FIG. 48, the top surfaces 309TS of the bit line structures 301 may be recessed, and a plurality of landing pad layers 501 may be formed. A recessing process may be performed by a procedure similar to that illustrated in FIG. 25. The landing pad layers 501 may be formed by a procedure similar to that illustrated in FIGS. 27 to 29. The landing pad layer 501 may be formed to cover a portion 401P1 of a top surface 401TS of the capacitor contact structure 401 and an upper portion 401P2 of a sidewall 401SW of the capacitor contact structure 401.

One aspect of the present disclosure provides a semiconductor device comprising a substrate, a shallow trench isolation (STI) structure disposed in the substrate, a capacitor contact structure protruding from the substrate, and a landing pad covering a portion of a top surface of the capacitor contact structure and an upper portion of a sidewall of the capacitor contact structure. The substrate comprises a bottom semiconductor layer, a top semiconductor layer disposed over the bottom semiconductor layer, and a buried insulating layer disposed between the top semiconductor layer and the bottom semiconductor layer.

In some embodiments, the shallow trench isolation (STI) structure penetrates through the top semiconductor layer and the buried insulating layer and extends into the bottom semiconductor layer.

In some embodiments, the shallow trench isolation (STI) structure comprises a first liner disposed in the substrate, a second liner disposed over the first liner, a third liner disposed over the second liner, and a trench-filling layer disposed over the third liner and separated from the second liner by the third liner.

In some embodiments, the first liner comprises a first portion and a second portion covering opposite sidewalls of the buried insulating layer, and a third portion separating the second liner from the bottom semiconductor layer.

In some embodiments, the first portion, the second portion and the third portion are separated from each other.

In some embodiments, the first liner, the second liner and the third liner are made of different materials.

In some embodiments, the bottom semiconductor layer and the top semiconductor layer are formed of silicon, and the buried insulating layer is formed of a nitride.

In some embodiments, the capacitor contact structure comprises a liner layer disposed on the substrate and extending into the substrate, a capacitor conductive structure disposed over and surrounded by the liner layer, and a spacer structure surrounding the capacitor conductive structure and separated from the capacitor conductive structure by the liner layer.

In some embodiments, a bottom surface of the liner layer is lower than a top surface of the substrate, and the bottom surface of the liner layer is higher than a bottom surface of the buried insulating layer.

In some embodiments, an angle between a sidewall of the liner layer and the bottom surface of the liner layer is greater than 90 degrees.

In some embodiments, the capacitor conductive structure extends into the substrate and has a tapered profile.

In some embodiments, the capacitor conductive structure comprises a barrier layer conformally disposed over and surrounded by the liner layer, a metal layer disposed over and surrounded by the barrier layer, and a metal filling portion disposed over and surrounded by the metal layer.

In some embodiments, the metal filling portion has a top width and a bottom width, wherein the top width is greater than the bottom width.

In some embodiments, the spacer structure comprises an L-shaped liner and a porous low-k dielectric layer disposed over the L-shaped liner.

In some embodiments, the porous low-k dielectric layer is enclosed by the liner layer and the L-shaped liner.

Another aspect of the present disclosure provides a semiconductor device comprising a substrate with a plurality of shallow trench isolation (STI) structures disposed therein, a capacitor contact structure disposed in the substrate and protruding from the substrate, a bit line structure disposed on the substrate and disposed next to the capacitor contact structure, a bit line contact disposed under the bit line structure, and a landing pad covering a portion of a top surface of the capacitor contact structure and an upper portion of a sidewall of the capacitor contact structure.

In some embodiments, the substrate comprises a bottom semiconductor layer, a top semiconductor layer disposed over the bottom semiconductor layer, and a buried insulating layer disposed between the top semiconductor layer and the bottom semiconductor layer.

In some embodiments, the shallow trench isolation (STI) structures define an active area, and a plurality of source/drain regions are disposed in the active area.

In some embodiments, the shallow trench isolation (STI) structure penetrates through the top semiconductor layer and the buried insulating layer and extends into the bottom semiconductor layer.

In some embodiments, the shallow trench isolation (STI) structure comprises a first liner disposed in the substrate, a second liner disposed over the first liner, a third liner disposed over the second liner, and a trench-filling layer disposed over the third liner and separated from the second liner by the third liner.

In some embodiments, the first liner comprises a first portion and a second portion covering opposite sidewalls of the buried insulating layer, and a third portion separating the second liner from the bottom semiconductor layer.

In some embodiments, the first portion, the second portion and the third portion are separated from each other.

In some embodiments, the first liner, the second liner and the third liner are made of different materials.

In some embodiments, the capacitor contact structure comprises a liner layer disposed on the substrate and extending into the substrate, a capacitor conductive structure disposed over and surrounded by the liner layer, and a spacer structure surrounding the capacitor conductive structure and separated from the capacitor conductive structure by the liner layer.

In some embodiments, a bottom surface of the liner layer is lower than a top surface of the substrate, and the bottom surface of the liner layer is higher than a bottom surface of the buried insulating layer.

In some embodiments, the capacitor conductive structure extends into the substrate and has a tapered profile.

In some embodiments, the capacitor conductive structure comprises a barrier layer conformally disposed over and surrounded by the liner layer, a metal layer disposed over and surrounded by the barrier layer, and a metal filling portion disposed over and surrounded by the metal layer.

In some embodiments, the metal filling portion has a top width and a bottom width, wherein the top width is greater than the bottom width.

In some embodiments, the spacer structure comprises an L-shaped liner and a porous low-k dielectric layer disposed over the L-shaped liner.

In some embodiments, the porous low-k dielectric layer is enclosed by the liner layer and the L-shaped liner.

In some embodiments, a top surface of the bit line structure is at a vertical level lower than a vertical level of a top surface of the capacitor contact structure.

In some embodiments, the semiconductor device further comprises a bit line spacer disposed between the capacitor contact structure and the bit line structure.

In some embodiments, a top surface of the bit line spacer is substantially coplanar with the top surface of the bit line structure.

In some embodiments, the bit line structure comprises a bit line bottom conductive layer disposed on the substrate, a bit line middle conductive layer disposed on the bit line bottom conductive layer, a bit line top conductive layer disposed on the bit line middle conductive layer, and a bit line capping layer disposed on the bit line top conductive layer.

In some embodiments, a top surface of the bit line contact is substantially coplanar with a top surface of the substrate.

Another aspect of the present disclosure provides a method for fabricating a semiconductor device comprising providing a substrate, forming a bit line structure on the substrate, forming a capacitor contact structure next to the bit line structure, recessing a top surface of the bit line structure, and forming a landing pad layer covering a portion of a top surface of the capacitor contact structure and an upper portion of a sidewall of the capacitor contact structure.

In some embodiments, the formation of the bit line structure comprises forming a bit line bottom conductive layer on the substrate, forming a bit line middle conductive layer on the bit line bottom conductive layer, forming a bit line top conductive layer on the bit line middle conductive layer, and forming a bit line capping layer on the bit line top conductive layer.

In some embodiments, the formation of the capacitor contact structure comprises forming a spacer structure on the substrate, forming a liner layer on the substrate and extending into the substrate, wherein the liner layer is surrounded by the spacer structure, and forming a capacitor conductive structure over and surrounded by the liner layer, wherein the capacitor conductive structure comprises a barrier layer conformally disposed over and surrounded by the liner layer, a metal layer disposed over and surrounded by the barrier layer, and a metal filling portion disposed over and surrounded by the metal layer.

In some embodiments, the method further comprises forming a bit line spacer between the capacitor contact structure and the bit line structure, wherein a top surface of the bit line spacer is substantially coplanar with the top surface of the bit line structure.

In some embodiments, the method further comprises forming a bit line contact under the bit line structure.

In some embodiments, the method further comprises forming source/drain regions under the bit line contact and the capacitor contact structure.

In some embodiments, the method further comprises forming a shallow trench isolation (STI) structure in the substrate.

In some embodiments, the formation of the shallow trench isolation (STI) structure comprises forming a first liner in the substrate, forming a second liner disposed over the first liner, forming a third liner disposed over the second liner, and forming a trench-filling layer disposed over the third liner, wherein the trench-filling layer is separated from the second liner by the third liner.

Due to the design of the semiconductor device of the present disclosure, a contact surface between a landing pad layer and a capacitor contact structure may be increased. Accordingly, a resistance between the landing pad layer and the capacitor contact structure may be reduced. As a result, power consumption of the semiconductor device may be reduced. In addition, a protruding capacitor contact structure may provide sufficient support for the landing pad layer.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate, comprising:
a bottom semiconductor layer;
a top semiconductor layer disposed over the bottom semiconductor layer; and
a buried insulating layer disposed between the top semiconductor layer and the bottom semiconductor layer;
a shallow trench isolation (STI) structure disposed in the substrate;
a capacitor contact structure protruding from the substrate; and
a landing pad covering a portion of a top surface of the capacitor contact structure and an upper portion of a sidewall of the capacitor contact structure.

2. The semiconductor device of claim 1, wherein the shallow trench isolation (STI) structure penetrates through the top semiconductor layer and the buried insulating layer and extends into the bottom semiconductor layer.

3. The semiconductor device of claim 2, wherein the shallow trench isolation (STI) structure comprises:
a first liner disposed in the substrate;
a second liner disposed over the first liner;
a third liner disposed over the second liner; and
a trench-filling layer disposed over the third liner and separated from the second liner by the third liner.

4. The semiconductor device of claim 3, wherein the first liner comprises:
a first portion and a second portion covering opposite sidewalls of the buried insulating layer; and
a third portion separating the second liner from the bottom semiconductor layer.

5. The semiconductor device of claim 4, wherein the first portion, the second portion and the third portion are separated from each other.

6. The semiconductor device of claim 5, wherein the first liner, the second liner and the third liner are made of different materials.

7. The semiconductor device of claim 1, wherein the bottom semiconductor layer and the top semiconductor layer are formed of silicon, and the buried insulating layer is a nitride.

8. The semiconductor device of claim 1, wherein the capacitor contact structure comprises:
a liner layer disposed on the substrate and extending into the substrate;
a capacitor conductive structure disposed over and surrounded by the liner layer; and
a spacer structure surrounding the capacitor conductive structure and separated from the capacitor conductive structure by the liner layer.

9. The semiconductor device of claim 8, wherein a bottom surface of the liner layer is lower than a top surface of the substrate, and the bottom surface of the liner layer is higher than a bottom surface of the buried insulating layer.

10. The semiconductor device of claim 9, wherein an angle between a sidewall of the liner layer and the bottom surface of the liner layer is greater than 90 degrees.

11. The semiconductor device of claim 8, wherein the capacitor conductive structure extends into the substrate and has a tapered profile.

12. The semiconductor device of claim 11, wherein the capacitor conductive structure comprises:
a barrier layer conformally disposed over and surrounded by the liner layer;
a metal layer disposed over and surrounded by the barrier layer; and
a metal filling portion disposed over and surrounded by the metal layer.

13. The semiconductor device of claim 12, wherein the metal filling portion has a top width and a bottom width, and the top width is greater than the bottom width.

14. The semiconductor device of claim 8, wherein the spacer structure comprises an L-shaped liner and a porous low-k dielectric layer disposed over the L-shaped liner.

15. The semiconductor device of claim 14, wherein the porous low-k dielectric layer is enclosed by the liner layer and the L-shaped liner.
